(19) United States
(12) Patent Application Publication
(10) Pub. No.: US 2014/0292433 A1
(43) Pub. Date: Oct. 2, 2014

(54) RESONATOR ELEMENT, RESONATOR, OSCILLATOR, ELECTRONIC APPARATUS, AND MOVING OBJECT

(71) Applicant: SEIKO EPSON CORPORATION, Tokyo (JP)

(72) Inventors: Akinori Yamada, Ina-shi (JP); Shuhei Yoshida, Minowa-machi (JP)

(73) Assignee: SEIKO EPSON CORPORATION, Tokyo (JP)

(21) Appl. No.: 14/224,624

(22) Filed: Mar. 25, 2014

(30) Foreign Application Priority Data
Mar. 29, 2013 (JP) 2013-075411
Feb. 6, 2014 (JP) 2014-021141

(51) Int. Cl. H03H 9/21; H03B 5/32

(52) U.S. Cl. CPC H03H 9/21; H03B 5/32
USPC 331/156; 310/370

(57) ABSTRACT

A resonator element includes a base portion and a pair of vibrating arms that are provided integrally with the base portion and extend in a Y-axis direction from a distal end of the base portion. When the lengths of the vibrating arms are set to L and the lengths of hammerheads are set to H, a relation of 0.183≦H/L≦0.597 is satisfied. When a resonance frequency of a basic vibration mode is set to ω0 and a resonance frequency of a vibration mode different from the basic vibration mode is set to ω1, a relation of (|ω0−ω1|)/ω0≧0.124 is satisfied.

### BACKGROUND

1. Technical Field

The present invention relates to a resonator element, a resonator, an oscillator, an electronic apparatus, and a moving object.

2. Related Art

Hitherto, resonator elements using quartz crystal have been known. Such a resonator element has been widely used as a reference frequency source, a signal transmission source, or the like of various electronic apparatuses because of its excellent frequency-temperature characteristics.

A resonator element disclosed in JP-A-2011-19159 is a tuning fork type element. The resonator element includes a base portion and a pair of vibrating arms extending from the base portion. The resonator element is driven in a basic vibration mode (X reverse phase mode) in which the pair of vibrating arms vibrate to opposite sides in an X-axis direction by alternately repeating mutual approach and separation. In addition, in the resonator element disclosed in JP-A-2011-19159, a hammerhead as a weight portion is formed in a distal end portion of each vibrating arm for the purpose of preventing the vibration of second high harmonics, and the length of the hammerhead is set to equal to or greater than 30% of the total length of the vibrating arm. However, in a resonator element that is simply configured in such a manner, when the hammerhead has a length that is longer than 51% of the total length of the vibrating arm, the vibration frequency of a basic vibration mode increases due to stiffness of the hammerhead. That is, it becomes difficult to reduce the size of the resonator element, and thermoelastic loss occurring in the vibrating arm may increase. In addition, an unnecessary vibration mode (for example, X in-phase mode in which a pair of vibrating arms vibrate to the same side in an X-axis direction) other than the basic vibration mode may be coupled to the basic vibration mode, and thus there is a problem in that vibration characteristics deteriorate (vibration loss increases).

### SUMMARY

An advantage of some aspects of the invention is to provide a resonator element which is small in size and is capable of reducing deterioration of vibration characteristics, and a resonator, an oscillator, an electronic apparatus, and a moving object which include the resonator element.

The invention can be implemented as the following application examples.

### Application Example 1

This application Example is directed to a resonator element including: a base portion; and a pair of vibrating arms that extend in a first direction from the base portion when seen in a plan view and are lined up along a second direction perpendicular to the first direction. The vibrating arm includes a weight portion, and an arm portion that is disposed between the weight portion and the base portion when seen in a plan view. The resonator element has a basic vibration mode in which the pair of vibrating arms bend and vibrate by alternately repeating mutual approach and separation along the second direction. When a length of the vibrating arm along the first direction is set to L and a length of the weight portion along the first direction is set to H, the following relation is satisfied.

$$0.183 ≦ \frac{H}{L} ≦ 0.597$$

When a resonance frequency of the basic vibration mode is set to ω0 and a resonance frequency of another vibration mode different from the basic vibration mode is set to ω1, the following relation is satisfied.

$$\frac{\vert ω 0 - ω 1 \vert}{ω 0} ≧ 0.124$$

With this configuration, it is possible to obtain the resonator element which is small in size and is capable of reducing deterioration of vibration characteristics.

### Application Example 2

In the resonator element according to the application example described above, it is preferable that a groove is provided in at least one of a pair of principal surfaces of the vibrating arm which have a front-back relationship. When a thickness of the vibrating arm is set to T and a depth of the groove is set to t, it is preferable that the following relation is satisfied.

$$0.375 ≦ \frac{t}{T} ≦ 0.483$$

In the one principal surface of the vibrating arm, when a width along the second direction between one outer edge of the vibrating arm and an edge portion of the groove on the one outer edge side and a width along the second direction between the other outer edge of the vibrating arm and an edge portion of the groove on the other outer edge side, when seen in a plan view, are set to W[μm], it is preferable that the following relation is satisfied.

$$- 8.835 \times {10}^{1} \times {( \frac{t}{T} )}^{2} + 8.737 \times {10}^{1} \times ( \frac{t}{T} ) - 1.872 \times {10}^{1} ≦ W ≦ 1.136 \times {10}^{2} \times {( \frac{t}{T} )}^{2} - 1.385 \times {10}^{2} \times ( \frac{t}{T} ) + 5.205 \times {10}^{1}$$

With this configuration, it is possible to obtain the resonator element capable of reducing thermoelastic loss, obtaining a high Q value, and exhibiting excellent vibration characteristics.

### Application Example 3

In the resonator element according to the application example described above, it is preferable that the following relation is satisfied.

$$0.455 ≦ \frac{t}{T} ≦ 0.483$$

With this configuration, it is possible to obtain the resonator element capable of particularly reducing thermoelastic loss, obtaining a higher Q value, and exhibiting excellent vibration characteristics.

### Application Example 4

In the resonator element according to the application example described above, it is preferable that a relation of 100 μm≦T≦300 μm is satisfied.

With this configuration, it is possible to obtain the resonator element having a particularly small CI value.

### Application Example 5

In the resonator element according to the application example described above, when a resonance frequency of the basic vibration mode is set to f and a relaxation vibration frequency is set to fm, it is preferable that the following relation is satisfied.

$$\frac{f}{fm} > 1$$

With this configuration, it is possible to set the vibrating arm as an adiabatic region and to obtain the resonator element having a high Q value.

### Application Example 6

In the resonator element according to the application example described above, it is preferable that the another vibration mode is an in-phase mode in which the pair of vibrating arms are displaced in the same direction.

With this configuration, it is possible to reduce coupling of the in-phase mode to the basic vibration mode and to effectively reduce deterioration of vibration characteristics.

### Application Example 7

In the resonator element according to the application example described above, it is preferable that the weight portion has a width that is wider than a width of the arm portion along the second direction.

With this configuration, it is possible to sufficiently exhibit a weight effect and to efficiently manufacture the resonator element because the weight portion can be formed at the same time when a component such as the arm portion is formed.

### Application Example 8

This application example is directed to a resonator including: the resonator element according to the application example described above; and a package in which the resonator element is mounted.

With this configuration, it is possible to obtain the resonator with high reliability.

### Application Example 9

This application example is directed to an oscillator including the resonator element according to the application example described above; and a circuit.

With this configuration, it is possible to obtain the oscillator with high reliability.

### Application Example 10

This application example is directed to an electronic apparatus including the resonator element according to the application example described above.

With this configuration, it is possible to obtain the electronic apparatus with high reliability.

### Application Example 11

This application example is directed to a moving object including the resonator element according to the application example described above.

With this configuration, it is possible to obtain the moving object with high reliability.

### BRIEF DESCRIPTION OF THE DRAWINGS

The invention will be described with reference to the accompanying drawings, wherein like numbers reference like elements.

FIG. 1 is a plan view of a resonator according to a first embodiment of the invention.

FIG. 2 is a cross-sectional view taken along a line A-A of FIG. 1.

FIG. 3 is a cross-sectional view taken along a line B-B of FIG. 1.

FIG. 4 is a graph showing a relationship between H/L and a normalization value.

FIG. 5 is a perspective view showing the shape and the size of a vibrating arm used in simulation.

FIG. 6 is a graph showing a relationship between H/L and a high performance index 1.

FIG. 7 is a cross-sectional view of a vibrating arm illustrating heat conduction when the vibrating arm bends and vibrates.

FIG. 8 is a graph showing a relationship between a Q value and f/fm.

FIG. 9 is a cross-sectional view showing a vibrating arm formed by wet etching.

FIG. 10 is a graph showing a relationship between W and a high performance index 2.

FIG. 11 is a perspective view illustrating an effective width “a”.

FIG. 12 is a graph showing a relationship between H/L and W.

FIG. 13 is a graph showing a relationship between H/L and W.

FIG. 14 is a graph showing a relationship between H/L and W.

FIG. 15 is a plan view showing the shape and the size of a resonator element used in simulation.

FIG. 16 is a graph showing a relationship between Δf and a high performance index 3.

FIG. 17 is a top view of a resonator according to a second embodiment of the invention.

FIG. 18 is a top view of a resonator according to a third embodiment of the invention.

FIG. 19 is a plan view showing a resonator element according to a modification example.

FIG. 20 is a cross-sectional view of a vibrating arm of the resonator element according to the modification example.

FIG. 21 is a cross-sectional view showing an oscillator according to a preferred embodiment of the invention.

FIG. 22 is a perspective view showing a configuration of a mobile (or notebook) personal computer to which an electronic apparatus according to the invention is applied.

FIG. 23 is a perspective view showing a configuration of a mobile phone (PHS is also included) to which the electronic apparatus according to the invention is applied.

FIG. 24 is a perspective view showing a configuration of a digital still camera to which the electronic apparatus according to the invention is applied.

FIG. 25 is a perspective view showing a vehicle to which a moving object according to the invention is applied.

### DESCRIPTION OF EXEMPLARY EMBODIMENTS

Hereinafter, a resonator element, a resonator, an oscillator, an electronic apparatus, and a moving object will be described in detail on the basis of preferred embodiments shown in the drawings.

### 1. Resonator

First, the resonator according to the invention will be described.

### First Embodiment

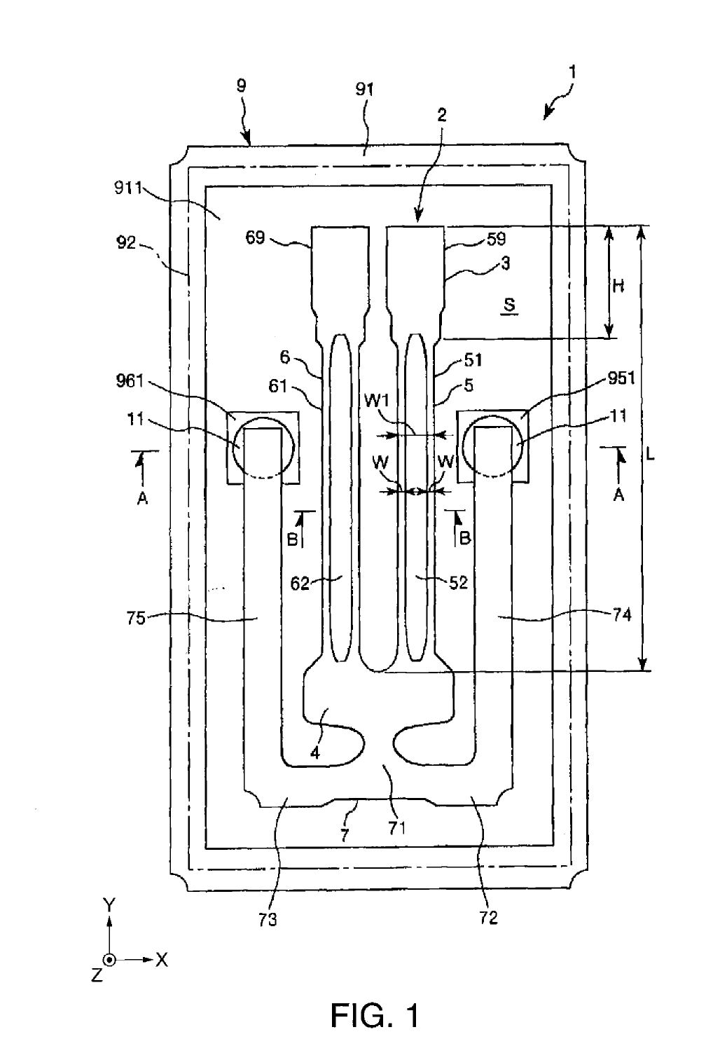

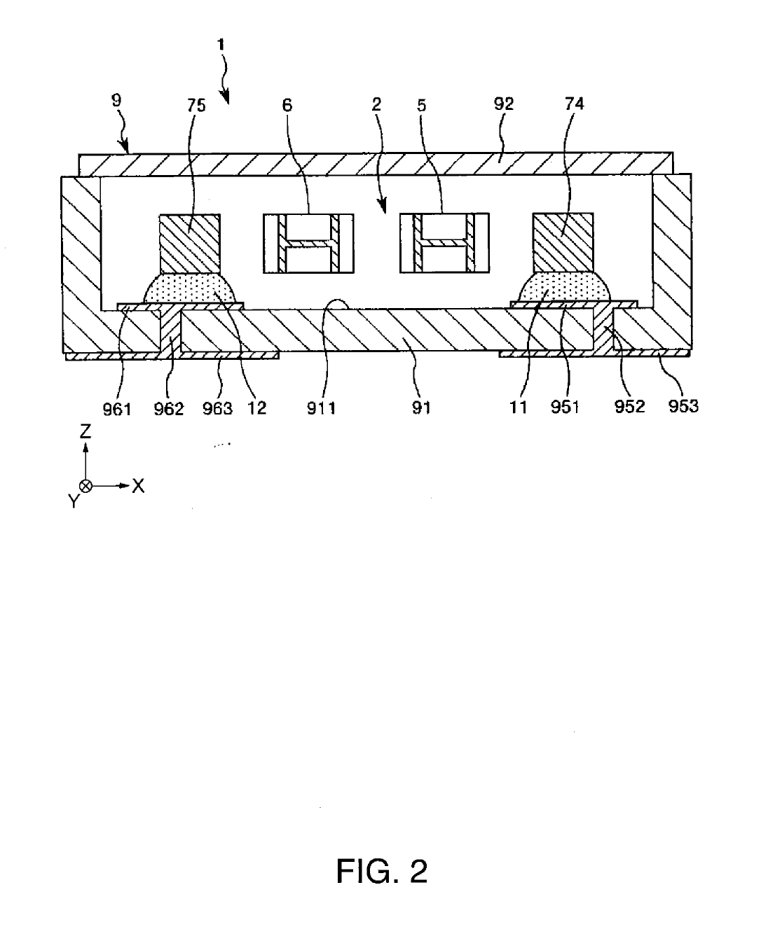

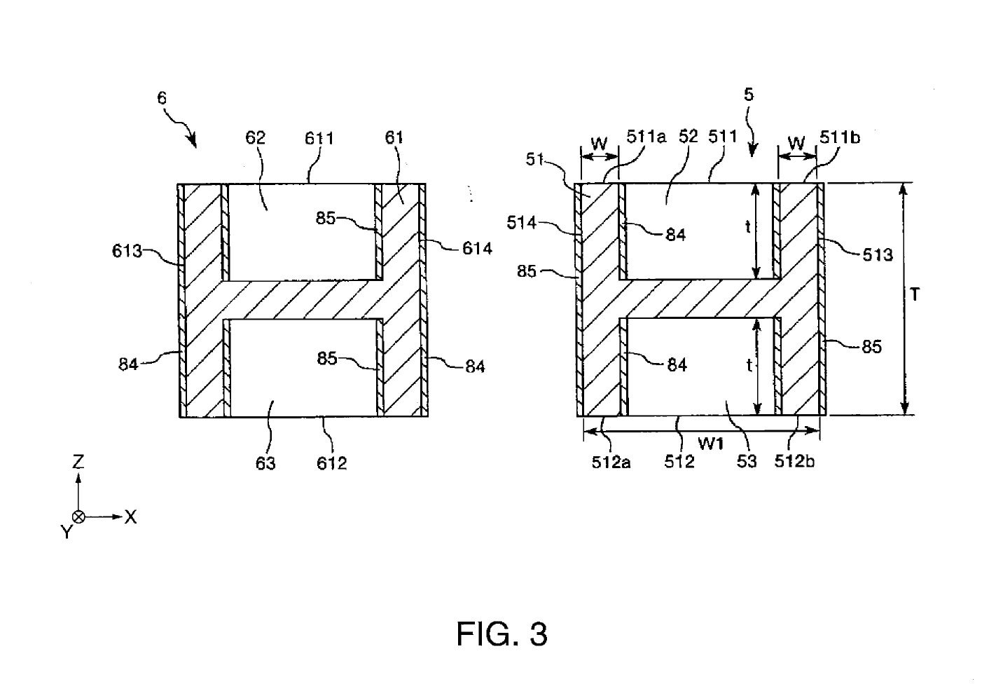

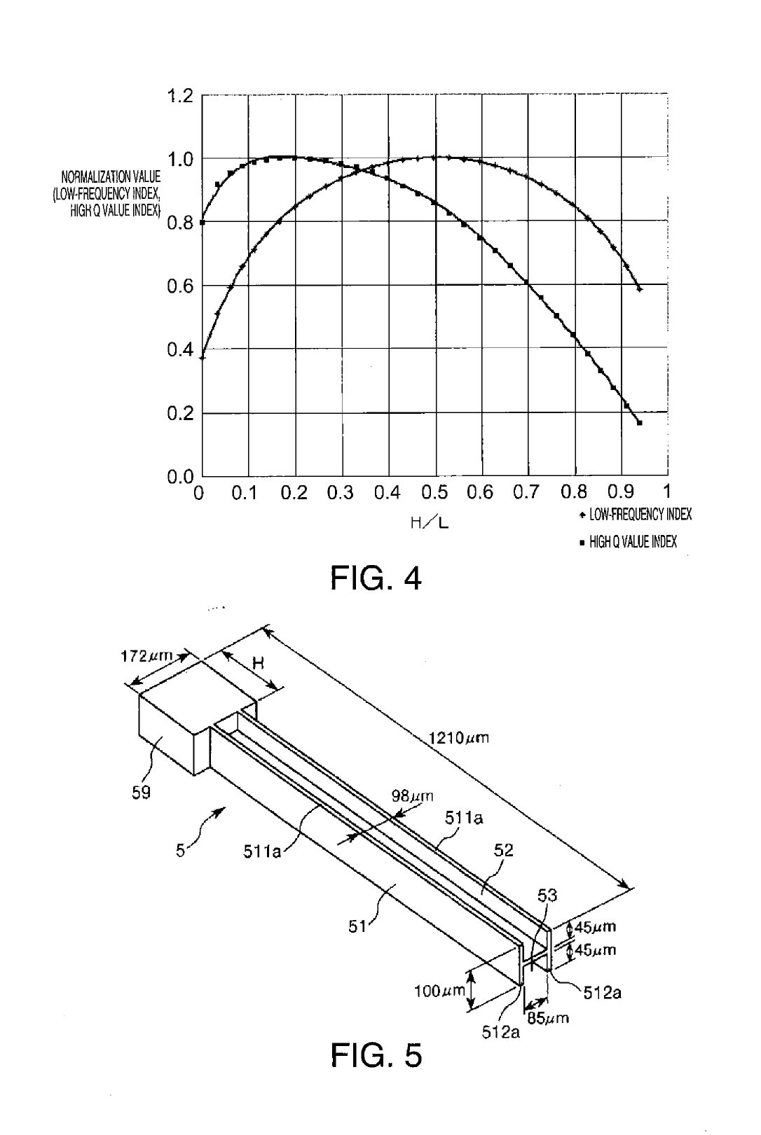

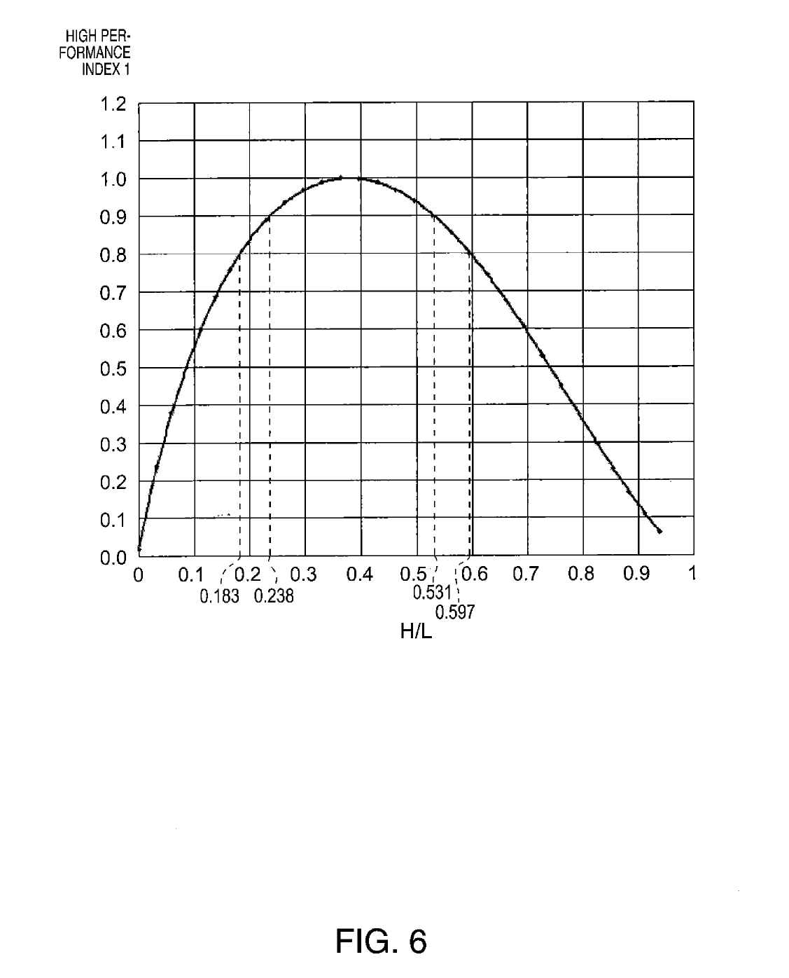

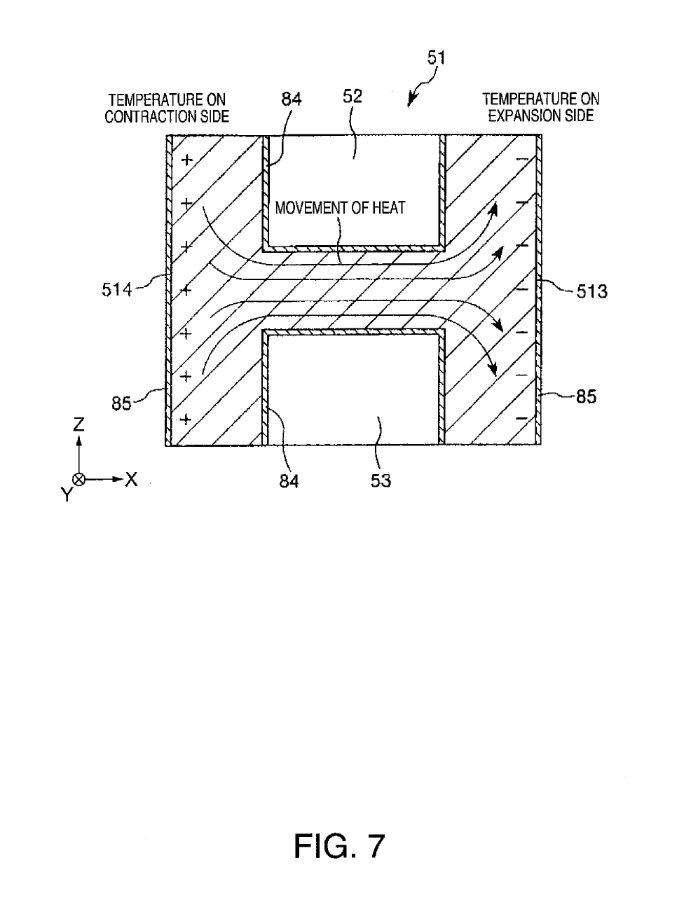

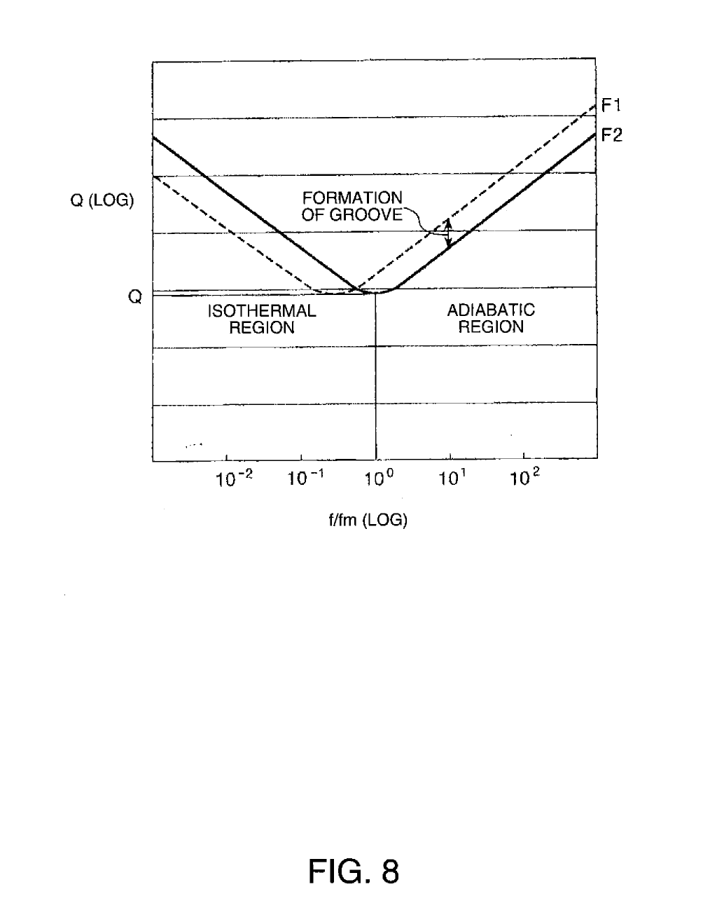

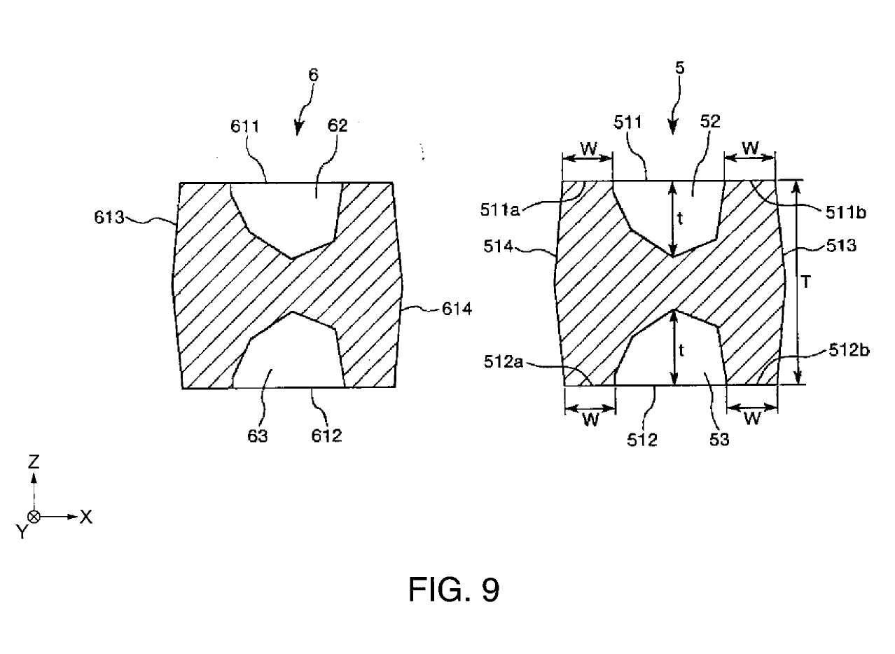

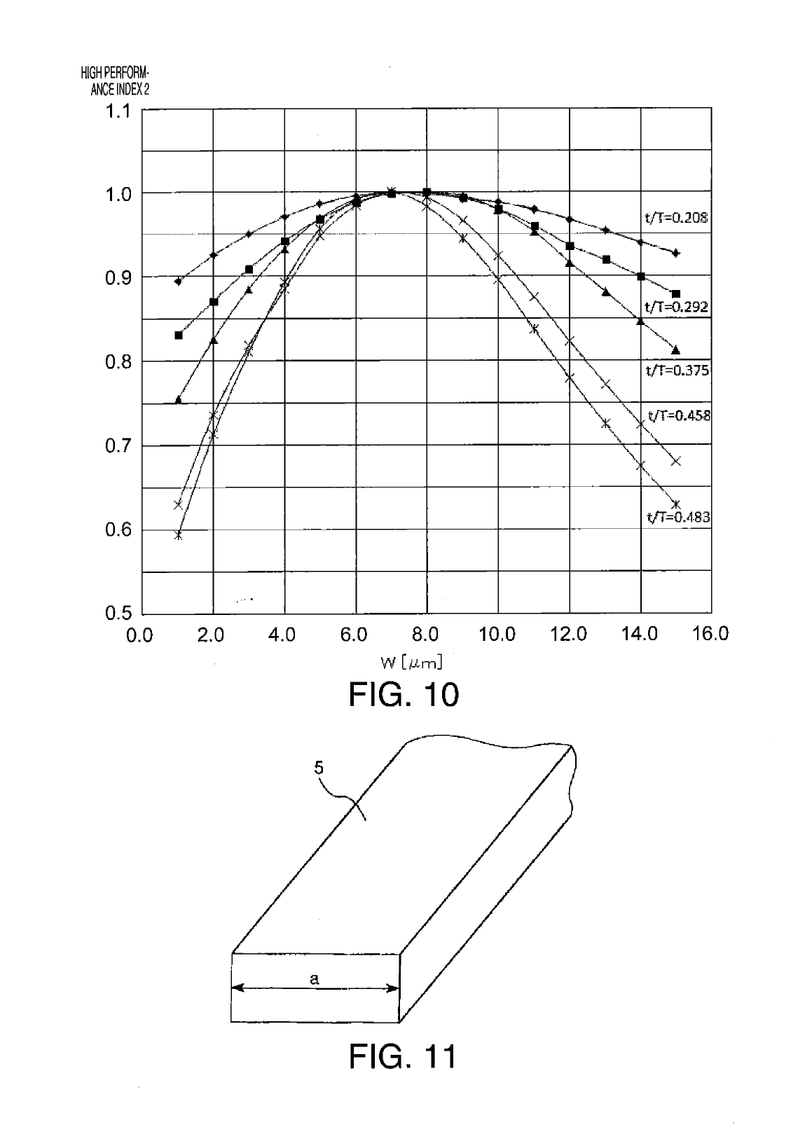

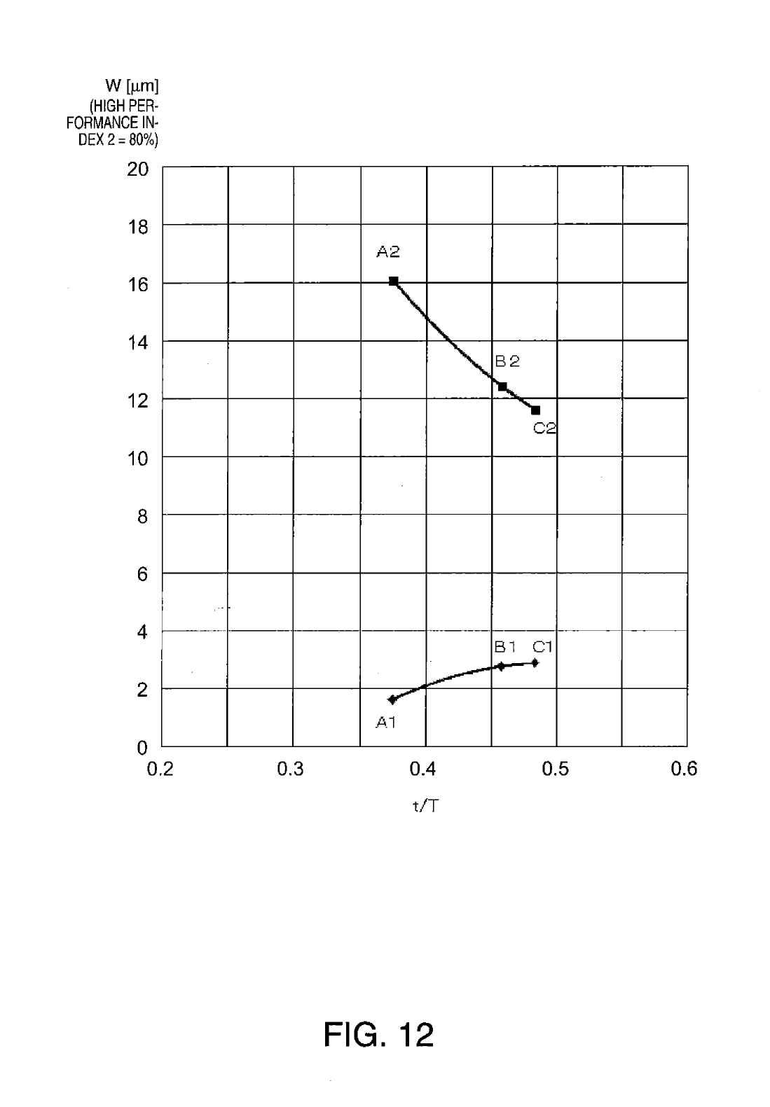

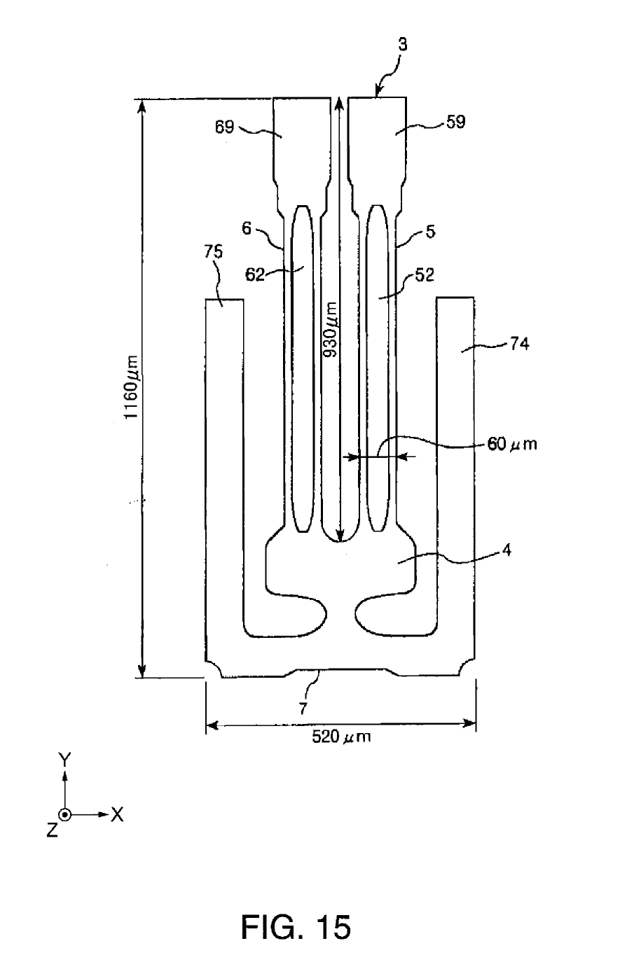

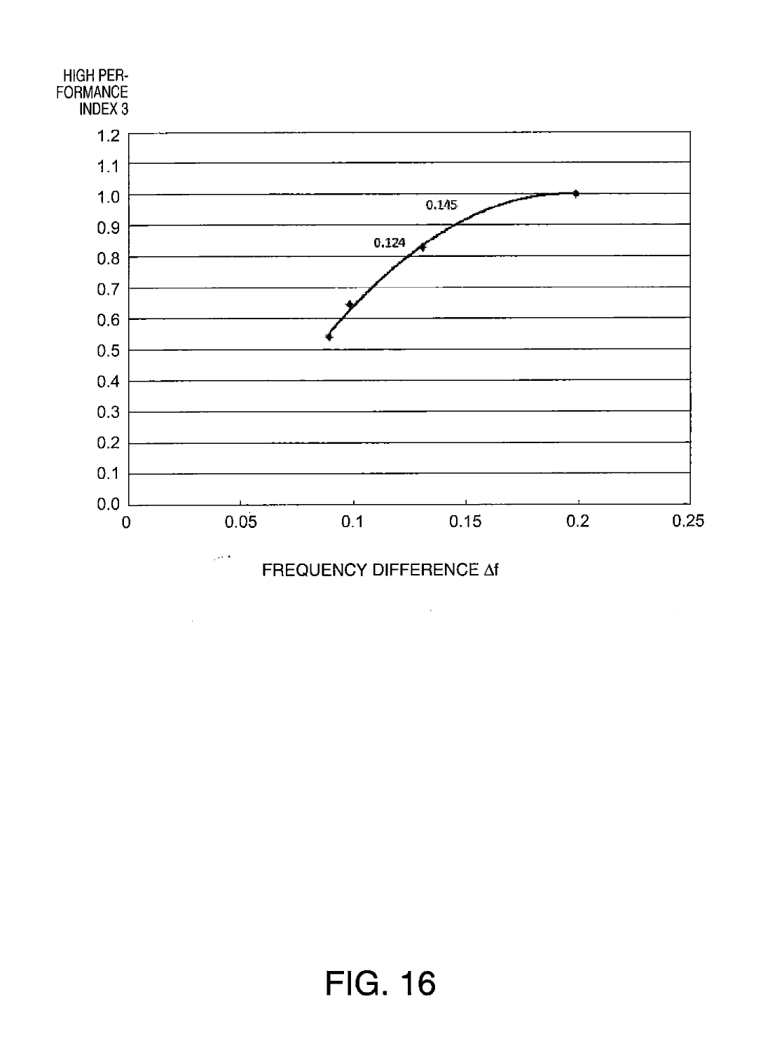

FIG. 1 is a plan view of a resonator according to a first embodiment of the invention. FIG. 2 is a cross-sectional view taken along a line A-A of FIG. 1. FIG. 3 is a cross-sectional view taken along a line B-B of FIG. 1. FIG. 4 is a graph showing a relationship between H/L and a normalization value. FIG. 5 is a perspective view showing the shape and the size of a vibrating arm used in simulation. FIG. 6 is a graph showing a relationship between H/L and a high performance index 1. FIG. 7 is a cross-sectional view of a vibrating arm illustrating heat conduction when the vibrating arm bends and vibrates. FIG. 8 is a graph showing a relationship between a Q value and f/fm. FIG. 9 is a cross-sectional view showing a vibrating arm formed by wet etching. FIG. 10 is a graph showing a relationship between W and a high performance index 2. FIG. 11 is a perspective view illustrating an effective width “a”. FIGS. 12 through 14 are graphs showing a relationship between H/L and W. FIG. 15 is a plan view showing the shape and the size of a resonator element used in simulation. FIG. 16 is a graph showing a relationship between Δf and a high performance index 3.

Meanwhile, hereinafter, as shown in FIG. 1, three axes perpendicular to each other are assumed to be an X-axis (electrical axis of quartz crystal), a Y-axis (mechanical axis of quartz crystal), and a Z-axis (optical axis of quartz crystal) for convenience of description. In addition, the upper side and the lower side in FIG. 2 are assumed to be a “top” and a “bottom”, respectively. In addition, the upper side and the lower side in FIG. 1 are assumed to be a “distal end” and a “base end”, respectively.

As shown in FIG. 1, a resonator 1 includes a resonator element (resonator element according to the invention) 2 and a package 9 accommodating the resonator element 2.

### Package

As shown in FIG. 1 and FIG. 2, the package 9 includes a box-shaped base 91 having a concave portion 911, which is opened on a top surface, and a plate-shaped lid 92 bonded to the base 91 so as to close an opening of the concave portion 911. The package 9 has an accommodation space S formed by closing the concave portion 911 with the lid 92, and the resonator element 2 is accommodated in the accommodation space S in an airtight manner. The inside of the accommodation space S may be set to be in a decompressed (preferably, vacuum) state, or inert gas such as nitrogen, helium, or argon may be enclosed within the accommodation space S.

Although materials of the base 91 are not particularly limited, various ceramics such as aluminum oxide can be used. In addition, although materials of the lid 92 are not particularly limited, it is preferable to use a member having a linear expansion coefficient similar to that of the material of the base 91. For example, when the above-described ceramic is used as a material of the base 91, it is preferable to use an alloy such as Kovar. Meanwhile, although bonding between the base 91 and the lid 92 is not particularly limited, it is possible to bond the base and the lid to each other through, for example, a metalization layer.

In addition, connecting terminals 951 and 961 are formed on the bottom of the concave portion 911 of the base 91. A first conductive adhesive member (fixing member) 11 is provided on the connecting terminal 951, and a second conductive adhesive member (fixing member) 12 is provided on the connecting terminal 961. The resonator element 2 is fixed to the base 91 through the first and second conductive adhesive members 11 and 12, the connecting terminal 951 is electrically connected to a first driving electrode 84 to be described later, and the connecting terminal 961 is electrically connected to a second driving electrode 85. Meanwhile, materials of the first and second conductive adhesive members 11 and 12 are not particularly limited as long as the materials have conductivity and adhesiveness. For example, a conductive adhesive member including an epoxy-based, acrylic-based, silicon-based, polyimide-based, bismaleimide-based, polyester-based, or polyurethane-based resin mixed with a conductive filler such as silver particles can be used as the materials of the first and second conductive adhesive members.

In addition, the connecting terminal 951 is electrically connected to an external terminal 953, provided on the bottom of the base 91, through a penetrating electrode 952 passing through the base 91. Similarly, the connecting terminal 961 is electrically connected to an external terminal 963, provided on the bottom of the base 91, through a penetrating electrode 962 passing through the base 91. Materials of the connecting terminals 951 and 961, the penetrating electrodes 952 and 962, and the external terminals 953 and 963 are not particularly limited as long as the materials have conductivity. For example, the connecting terminals, the penetrating electrodes, and the external terminals can be formed of a metal coating in which a coat such as gold (Au), silver (Ag), or copper (Cu) is laminated on a ground layer such as chromium (Cr), nickel (Ni), or tungsten (W).

### Resonator Element

As shown in FIG. 1 and FIG. 3, the resonator element 2 includes a quartz crystal substrate 3 and first and second driving electrodes 84 and 85 formed on the quartz crystal substrate 3. Meanwhile, the first and second driving electrodes 84 and 85 are not shown in FIGS. 1 and 2 for convenience of description.

The quartz crystal substrate 3 is constituted by a Z-cut quartz crystal plate. The Z-cut quartz crystal plate is a quartz crystal substrate having a Z-axis as its thickness direction. Meanwhile, it is preferable that the Z-axis conform with the thickness direction of the quartz crystal substrate 3. However, from the viewpoint of reducing a frequency temperature change near a room temperature, the Z-axis may be inclined slightly with respect to the thickness direction.

That is, in a case where the inclination angle is set to θ degrees (−5°≦θ≦15°, it is assumed that an X-axis of a Cartesian coordinate system constituted by the X-axis as an electrical axis of the quartz crystal, a Y-axis as a mechanical axis thereof, and a Z-axis as an optical axis thereof is a rotation axis. When an axis obtained by inclining the Z-axis at θ degrees so that a +Z side rotates in a −Y direction of the Y-axis is set to a Z′-axis and an axis obtained by inclining the Y-axis at θ degrees so that a +Y side rotates in a +Z direction of the Z-axis is set to a Y′-axis, the quartz crystal substrate 3 is obtained in which a direction along the Z′-axis is set to the thickness thereof and a surface including the X-axis and the Y′-axis is set to the principal surface thereof.

Meanwhile, the thickness T of the quartz crystal substrate 3 is not particularly limited, but is preferably less than 70 μm, and more preferably equal to or less than 60 μm. Based on such a numerical range, when the quartz crystal substrate 3 is formed (patterned) by, for example, wet etching, it is possible to effectively prevent an unnecessary portion (portion to be removed naturally) from remaining in a boundary between a vibrating arm 5 and a base portion 4, a boundary between an arm portion 51 to be described later and a hammerhead 59 as a weight portion, and the like. For this reason, it is possible to obtain the resonator element 2 capable of effectively reducing vibration leakage. From a different point of view, the thickness T is preferably equal to or greater than 70 μm and equal to or less than 300 μm, and more preferably equal to or greater than 100 μm and equal to or less than 300 μm. Based on such a numerical range, it is possible to form the first and second driving electrodes 84 and 85 to be described later to be wide in the side surfaces of the vibrating arm 5 and a vibrating arm 6, and thus it is possible to lower a CI value.

As shown in FIG. 1, the base portion 4 has a plate shape that has a spread in the XY plane thereof and has a thickness in the Z-axis direction.

A support portion 7 includes a branch portion 71 that extends from a base end of the base portion 4 and is branched in the X-axis direction, connecting arms 72 and 73 that extend from the branch portion to both sides in the X-axis direction, and support arms 74 and 75 that extend from distal ends of the connecting arms 72 and 73 to the vibrating arms 5 and 6 sides in the Y-axis direction.

The vibrating arms 5 and 6 extend from an upper end of the base portion 4 in the Y-axis direction (first direction) so as to be lined up in the X-axis direction (second direction) and to be parallel to each other. The vibrating arms 5 and 6 have a longitudinal shape in which the base end thereof is a fixed end and the distal end thereof is a free end. In addition, the vibrating arm 5 includes the arm portion 51 and the hammerhead (wide width portion) 59 as a weight portion provided in the distal end of the arm portion 51, and the vibrating arm 6 includes an arm portion 61 and a hammerhead (wide width portion) 69 as a weight portion provided in the distal end of the arm portion 61. Meanwhile, since the vibrating arms 5 and 6 have similar configurations, the vibrating arm 5 will be described below as a representative vibrating arm, and a description of the vibrating arm 6 will be omitted.

The hammerheads 59 and 69 as weight portions are configured as wide width portions of which the lengths along the X-axis direction are longer than those of the arm portions 51 and 61. However, the invention is not limited thereto, and the mass per unit length of the hammerheads may be greater than those of the arm portions 51 and 61. For example, the weight portion may be configured to have a length that is the same as the lengths along the X-axis direction of the arm portions 51 and 61 and to have a thickness along the Z-axis direction which is larger than those of the arm portions. In addition, the weight portion may be configured such that a metal such as Au is provided thickly on the surfaces of the arm portions 51 and 61 which correspond to the weight portion. Further, the weight portion may be formed of a material having a higher mass density than those of the arm portions 51 and 61.

As shown in FIG. 3, the arm portion 51 has a pair of principal surfaces 511 and 512 constituted in an XY plane and a pair of side surfaces 513 and 514 constituted in a YZ plane and connecting the pair of principal surfaces 511 and 512 to each other. In addition, the arm portion 51 has a bottomed groove 52 opened to the principal surface 511 and a bottomed groove 53 opened to the principal surface 512. In this manner, the grooves 52 and 53 are formed in the vibrating arm 5, and thus it is possible to reduce thermoelastic loss and to exhibit excellent vibration characteristics. The lengths of the grooves 52 and 53 are not particularly limited, and the distal ends thereof may extend up to the hammerhead 59 and the base ends thereof may extend up to the base portion 4. Based on such a configuration, stress concentrated on the boundary between the arm portion 51 and the hammerhead 59 and the boundary between the arm portion 51 and the base portion 4 is reduced, and a possibility of breakage and cracking that occur when an impact is applied thereto is reduced.

When the depth of each of the grooves 52 and 53 is set to t, it is preferable that the depth t satisfy the relation of 0.292≦t/T≦0.483. Since a heat transfer path becomes long by satisfying such a relation, it is possible to more effectively reduce thermoelastic loss in an adiabatic region to be described later. In addition, it is more preferable that the depth t satisfy the relation of 0.455≦t/T≦0.483. Since a heat transfer path becomes long by satisfying such a relation, it is possible to reduce thermoelastic loss. Thus, an increase in Q value, a reduction in CI value which is associated with the increase in Q value, and a reduction in CI value by an electrode area for applying an electric field to a region, which bends and deforms, being further enlargeable are realized.

It is preferable that the grooves 52 and 53 be formed by adjusting the positions of the grooves in the X-axis direction with respect to the vibrating arm 5 so that the cross-sectional center of gravity of the vibrating arm 5 conforms with the center of the cross-sectional shape of the vibrating arm 5. In this manner, unnecessary vibration (specifically, oblique vibration having an out-of-plane direction component) of the vibrating arm 5 is reduced, and thus it is possible to reduce vibration leakage. In addition, in this case, since it is possible to reduce driving for unnecessary vibration, a driving region is relatively increased. Therefore, it is possible to reduce the CI value.

A width W1 of the arm portion 51 is not particularly limited, but is preferably equal to or greater than approximately 16 μm and equal to or less than approximately 300 μm. When the width W1 is less than the lower limit mentioned above, it becomes difficult to form the grooves 52 and 53 in the arm portion 51 depending on the manufacturing technique, and thus there are cases where it is not possible to set the vibrating arm 5 as an adiabatic region. On the other hand, when the width W1 exceeds the upper limit mentioned above, the stiffness of the arm portion 51 becomes excessively high depending on the value of the thickness T, and thus there are cases where it is not possible to smoothly perform the bending and vibration of the arm portion 51.

Subsequently, the size of the hammerhead 59 will be described. In the resonator element 2, when the total length (length in the Y-axis direction) of the vibrating arm 5 is set to L and the total length (length in the Y-axis direction) of the hammerhead 59 is set to H, the following Expression (1) is satisfied. Here, the hammerhead 59 is set as a region having a width of 1.5 times or more of the width (length in the X-axis direction) of the arm portion 51.

$$0.183 ≦ \frac{H}{L} ≦ 0.597 \qquad ( 1 )$$

Hereinafter, effects obtained by satisfying Expression (1) mentioned above will be described with reference to FIGS. 4 and 5. FIG. 4 shows a curve G1 obtained by indexing a relationship between the length H of the hammerhead 59 and a resonance frequency of the vibrating arm 5 and a curve G2 obtained by indexing a relationship between the length H of the hammerhead 59 and the Q value of the vibrating arm 5. Meanwhile, the Q value shown in the curve G2 is obtained by taking only thermoelastic loss into account. In addition, hereinafter, the vertical axis of the curve G1 is also referred to as a “low-frequency index”, and the vertical axis of the curve G2 is also referred to as a “high Q value index”.

In addition, simulation for obtaining the curves G1 and G2 was performed using only one vibrating arm 5. The vibrating arm 5 used in this simulation is constituted by a quartz crystal Z plate (rotation angle of 0 degrees). In addition, with regard to the size of the vibrating arm 5, as shown in FIG. 5, the total length L is 1210 μm, the thickness T is 100 μm, the width W1 of the arm portion 51 is 98 μm, the width W2 of the hammerhead 59 is 172 μm, the depth t of each of the grooves 52 and 53 is 45 μm, and the width W3 of each of bank portions 511a, 511b, 512a, and 512b is 6.5 μm. In such a vibrating arm 5, the simulation was performed while changing the length H of the hammerhead 59. Meanwhile, the inventors confirmed that results similar to the following simulation results were obtained even if the sizes (L, W1, W2, D, D1, D2, and W3) of the vibrating arm 5 were changed.

In FIG. 4, the curve G1 indicates that the resonance frequency of the vibrating arm 5 is lowest at the point (H/L=0.51) where a normalization value (low-frequency index)=1, and the curve G2 indicates that the Q value of the vibrating arm 5 is highest at the point (H/L=0.17) where a normalization value (high Q value index)=1. As the resonance frequency of the vibrating arm 5 decreases, it is possible to reduce the size of the resonator element 2. Thus, it is possible to minimize the size of the resonator element 2 by establishing the relation of H/L=0.51 (hereinafter, also referred to as “condition 1”). In addition, as the Q value is set to a higher value, thermoelastic loss becomes smaller, and thus it is possible to exhibit excellent vibration characteristics. Therefore, it is possible to obtain the resonator element 2 having the most excellent vibration characteristics by establishing the relation of H/L=0.17 (hereinafter, also referred to as “condition 2”).

However, as shown in FIG. 4, the high Q value index is not sufficiently high at the point of H/L=0.51, and the low-frequency index is not sufficiently high at the point of H/L=0.17. Therefore, it is not possible to obtain excellent vibration characteristics by merely satisfying the condition 1. In contrast, it is not possible to sufficiently reduce the size of the resonator element 2 by merely satisfying the condition 2.

Consequently, a “high performance index 1” is set as an index for succeeding in both reducing the size of the resonator element 2 and improving vibration characteristics, and a relationship between the high performance index 1 and H/L is shown in FIG. 6. Meanwhile, the “high performance index 1” is expressed as [low-frequency index]×[high Q value index]×[correction value]. In addition, the high performance index 1 is an index when the largest numerical value among values is set to 1. In addition, the [correction value] is a correction value for fitting the simulation performed using one vibrating arm 5 to the resonator element 2 having two vibrating arms 5 and 6. For this reason, it is possible to bring the high performance index 1 closer to physical properties of the resonator element 2 by using the correction value.

Here, if the high performance index 1 is equal to or greater than 0.8, the resonator element 2 sufficiently succeeding in both reducing the size and improving vibration characteristics is obtained. For this reason, in the resonator element 2, the length H of the hammerhead 59 is set to satisfy the relation of 0.183≦H/L≦0.597. That is, the resonator element 2 is configured to satisfy Expression (1) mentioned above. In addition, it is preferable to satisfy the relation of 0.238≦H/L≦0.531 so that the high performance index 1 is equal to or greater than 0.9 within the range of Expression (1). Thus, the resonator element 2 further succeeding in both reducing the size and improving vibration characteristics is obtained.

As shown in FIG. 3, the pair of first driving electrodes 84 and the pair of second driving electrodes 85 are formed in the vibrating arm 5. One of the first driving electrodes 84 is formed in the side surface of the groove 52, and the other is formed in the side surface of the groove 53. In addition, one of the second driving electrodes 85 is formed in the side surface 513, and the other is formed in the side surface 514.

Similarly, the pair of first driving electrodes 84 and the pair of second driving electrodes 85 are formed in the vibrating arm 6. One of the first driving electrodes 84 is formed in a side surface 613, and the other is formed in a side surface 614. In addition, one of the second driving electrodes 85 is formed in the side surface of a groove 62, and the other is formed in the side surface of a groove 66.

The first driving electrodes 84 are drawn up to the support arm 74 by a wiring not shown in the drawing and are electrically connected to the connecting terminal 951 through the conductive adhesive member 11. Similarly, the second driving electrodes 85 are drawn up to the support arm 75 by a wiring not shown in the drawing and are electrically connected to the connecting terminal 961 through the conductive adhesive member 12.

When an alternating voltage is applied between the first and second driving electrodes 84 and 85, the vibrating arms 5 and 6 vibrate with a predetermined frequency in the X-axis direction (in-plane direction) by mutually repeating approach and separation. This vibration mode is generally referred to as an “X reverse phase mode”, and hereinafter, this vibration mode will be also referred to as a “basic vibration mode”.

Materials of the first and second driving electrodes 84 and 85 are not particularly limited as long as the materials have conductivity. Examples of the materials include a metal material such as gold (Au), a gold alloy, platinum (Pt), aluminum (Al), an aluminum alloy, silver (Ag), a silver alloy, chromium (Cr), a chromium alloy, nickel (Ni), a nickel alloy, copper (Cu), molybdenum (Mo), niobium (Nb), tungsten (W), iron (Fe), titanium (Ti), cobalt (Co), zinc (Zn), zirconium (Zr) indium tin oxide (ITO), and the like.

In addition, as specific configurations of the first and second driving electrodes 84 and 85, a configuration can be adopted in which an Au layer of equal to or less than 700 Å is formed on a Cr layer of equal to or less than 700 Å, for example. In particular, since Cr and Au have a great thermoelastic loss, the Cr layer and the Au layer are preferably set to equal to or less than 200 Å. In addition, when insulation breakdown resistance is increased, the Cr layer and the Au layer are preferably set to equal to or greater than 1000 Å. Further, since Ni has a thermal expansion coefficient close to that of quartz crystal, thermal stress caused by electrodes is reduced by using a Ni layer as a foundation layer in place of the Cr layer, and thus it is possible to obtain a resonator element with a good long-term reliability (aging characteristics).

The configuration of the resonator element 2 has been described so far. As described above, the grooves 52 and 53 and the grooves 62 and 63 are formed in the vibrating arm 5 and the vibrating arm 6 of the resonator element 2, respectively, and thus it is possible to reduce thermoelastic loss and to exhibit excellent vibration characteristics, which will be described concretely below by using the vibrating arm 5 as an example.

As described above, the vibrating arm 5 bends and vibrates in the in-plane direction by applying an alternating voltage between the first and second driving electrodes 84 and 85. As shown in FIG. 7, at the time of the bending and vibration of the vibrating arm, the side surface 514 expands when the side surface 513 of the arm portion 51 contracts. In contrast, the side surface 514 contracts when the side surface 513 expands. When the vibrating arm 5 does not cause the Gough-Joule effect (when energy elasticity is dominant over the entropy elasticity), the temperature on the contracted surface side of the side surfaces 513 and 514 rises, and the temperature on the expanded surface side thereof drops. For this reason, a difference in temperature occurs between the side surface 513 and the side surface 514, in other words, inside the arm portion 51. Due to heat conduction resulting from such a difference in temperature, loss of vibration energy occurs. As a result, the Q value of the resonator element 2 is reduced. The loss of energy associated with such a reduction in the Q value is also referred to as thermoelastic loss.

In a resonator element that vibrates in a bending vibration mode and has the same configuration as the resonator element 2, when the bending vibration frequency (mechanical bending vibration frequency) f of the vibrating arm 5 changes, the Q value is minimized when the bending vibration frequency of the vibrating arm 5 conforms with a thermal relaxation frequency fm. The thermal relaxation frequency fm can be calculated by the following Expression (2) (where, in Expression (2), π denotes a circular constant, and τ denotes a relaxation time required for a difference in temperature to become e⁻¹ times by heat conduction, assuming that e is Napier's constant).

$$fm = \frac{1}{2 π τ} \qquad ( 2 )$$

In addition, assuming that the thermal relaxation frequency of the flat plate structure (structure having a rectangular cross-sectional shape) is fm0, fm0 can be calculated by the following Expression (3). Meanwhile, in Expression (3), π is a circular constant, k is the thermal conductivity in the vibration direction of the vibrating arm 5, ρ is the mass density of the vibrating arm 5, Cp is the heat capacity of the vibrating arm 5, and a is the width of the vibrating arm 5 in the vibration direction. When the constants of the material itself (that is, quartz crystal) of the vibrating arm 5 are input as the thermal conductivity k, the mass density ρ, and the heat capacity Cp in Expression (3), the calculated thermal relaxation frequency fm0 is a value when the grooves 52 and 53 are not provided in the vibrating arm 5.

$$fm 0 = \frac{π k}{2 ρ {Cpa}^{2}} \qquad ( 3 )$$

In the vibrating arm 5, the grooves 52 and 53 are formed so as to be located between the side surfaces 513 and 514. For this reason, since a heat transfer path for balancing a difference in temperature between the side surfaces 513 and 514, which is caused when the vibrating arm 5 bends and vibrates, by heat conduction is formed so as to bypass the grooves 52 and 53, thus the heat transfer path becomes longer than a straight-line distance (shortest distance) between the side surfaces 513 and 514. Therefore, the relaxation time τ becomes longer and the thermal relaxation frequency fm becomes lower, as compared with a case where the grooves 52 and 53 are not provided in the vibrating arm 5.

FIG. 8 is a graph showing the f/fm dependence of the Q value of the resonator element in the bending vibration mode. In FIG. 8, a curve F1 shown by a dotted line indicates a case where a groove is formed in a vibrating arm as in the resonator element 2, and a curve F2 shown by a solid line indicates a case where a groove is not formed in a vibrating arm. As shown in FIG. 8, the shapes of the curves F1 and F2 are not changed, but the curve F1 is shifted in a frequency decrease direction with respect to the curve F2 in association with a reduction in the thermal relaxation frequency fm mentioned above. Accordingly, assuming that the thermal relaxation frequency when a groove is formed in a vibrating arm as in the resonator element 2 is fm1, the Q value of the resonator element in which a groove is formed in the vibrating arm is always higher than the Q value of the resonator element in which a groove is not formed in the vibrating arm by satisfying the following Expression (4).

f>\sqrt{fmofm1} (4)

Further, it is possible to obtain a higher Q value when being limited to the relation of the following Expression (5).

$$\frac{f}{fm 0} > 1 \qquad ( 5 )$$

Meanwhile, in FIG. 8, the region of f/fm<1 is also referred to as an isothermal region. In this isothermal region, the Q value increases as f/fm decreases. This is because the above-described difference in temperature within the vibrating arm is not likely to occur when the mechanical frequency of the vibrating arm becomes low (vibration of the vibrating arm becomes slow). Accordingly, at a limit when f/fm approaches 0 (zero) infinitely, an isothermal quasi-static operation is realized, and thus thermoelastic loss approaches 0 (zero) infinitely. Meanwhile, the region of f/fm>1 is also referred to as an adiabatic region. In this adiabatic region, the Q value increases as f/fm increases. This is because the switching of temperature rise and temperature effect of each side surface becomes fast as the mechanical frequency of the vibrating arm becomes high, and accordingly, there is no time in which the above-described heat conduction occurs. Accordingly, at a limit when f/fm is increased infinitely, an adiabatic operation is realized, and thus thermoelastic loss approaches 0 (zero) infinitely. From this, it can be rephrased that f/fm is in the adiabatic region if the relation of f/fm>1 is satisfied.

Here, since the materials (metal materials) of the first and second driving electrodes 84 and 85 have higher thermal conductivity than quartz crystal which is the material of the vibrating arms 5 and 6, heat conduction through the first driving electrode 84 is actively performed in the vibrating arm 5 and heat conduction through the second driving electrode 85 is actively performed in the vibrating arm 6. When such heat conduction through the first and second driving electrodes 84 and 85 is actively performed, the relaxation time τ is shortened. Consequently, as shown in FIGS. 3 and 7, the first driving electrode 84 is divided into the side surface 513 side and the side surface 514 side at the bottom surfaces of the grooves 52 and 53 in the vibrating arm 5, and the second driving electrode 85 is divided into the side surface 613 side and the side surface 614 side at the bottom surfaces of the grooves 62 and 63 in the vibrating arm 6, thereby reducing the above-described heat conduction. As a result, the relaxation time τ is prevented from being reduced, and thus the resonator element 2 having a higher Q value is obtained.

The thermoelastic loss has been described so far.

It is preferable that the resonator element 2 be configured to obtain a higher Q value than that of a resonator element of the related art by satisfying Expression (5), and additionally, by forming the grooves 52 and 53 and the grooves 62 and 63 having a predetermined shape in the vibrating arms 5 and 6, respectively. Hereinafter, a specific description will be given of configurations of the grooves 52 and 53 and the grooves 62 and 63 which are formed in the vibrating arms 5 and 6, respectively. Since the vibrating arms 5 and 6 have a similar configuration, the grooves 52 and 53 formed in the vibrating arm 5 will be described below as representative grooves, and a description of the grooves 62 and 63 formed in the vibrating arm 6 will be omitted.

As shown in FIG. 3, when the thickness (length in the Z-axis direction) of the vibrating arm 5 is set to T, the maximum depth of each of the grooves 52 and 53 is set to t and the width of each of the bank portions (principal surfaces lined up with the groove 52 interposed therebetween along the width direction perpendicular to the longitudinal direction of the vibrating arm 5) 511a, 511b, 512a, and 512b, located on both sides of the grooves 52 and 53 of the principal surfaces 511 and 512 in the X-axis direction, is set to W[μm], it is preferable that the resonator element 2 satisfy both the following Expressions (6) and (7).

In other words, the bank portions 511a, 511b, 512a, and 512b are equivalent to a portion having the width W along the X-axis direction between the side surface 513, which is one outer edge of the arm portion 51 constituting the vibrating arm 5, and edge portions of the grooves 52 and 53 on one side surface 513 side and to a portion having the width W along the X-axis direction between the side surface 514, which is the other outer edge of the arm portion 51, and edge portions of the grooves 52 and 53 on the other side surface 514 side.

$$\begin{matrix} 0.375 ≦ \frac{t}{T} ≦ 0.483 & ( 6 ) \\ - 8.835 \times {10}^{1} \times {( \frac{t}{T} )}^{2} + 8.737 \times {10}^{1} \times ( \frac{t}{T} ) 1.872 \times {10}^{1} ≦ W ≦ 1.136 \times {10}^{2} \times {( \frac{t}{T} )}^{2} - 1.385 \times {10}^{2} \times ( \frac{t}{T} ) + 5.205 \times {10}^{1} & ( 7 )\end{matrix}$$

A region satisfying both Expressions (6) and (7) is present in at least a portion of the arm portion 51, and thus it is possible to obtain the resonator element 2 exhibiting more excellent vibration characteristics than that of the related art. Meanwhile, the region satisfying Expressions (6) and (7) may be present in a portion of the arm portion 51 in the longitudinal direction, but is preferably present in a base end portion of the arm portion 51. The base end portion is a portion of the arm portion 51 which greatly bends and deforms, and is a portion that is likely to affect the entire vibration characteristics of the vibrating arm 5. Therefore, it is possible to reliably and effectively obtain the resonator element 2 that exhibits more excellent vibration characteristics than that of the related art by causing the region to be present in at least the base end portion. In other words, it is possible to reliably and effectively obtain the resonator element 2 that exhibits more excellent vibration characteristics than that of the related art by causing the region to be present in at least a portion having the greatest amount of bending deformation of the vibrating arm 5.

In the resonator element 2, the arm portion 51 is configured to have an equal width and thickness in substantially the whole region except for both the end portions thereof, and additionally, the grooves 52 and 53 are configured to have an equal width and depth in substantially the whole region except for both the end portions thereof. For this reason, it is possible to cause the region to be present lengthwise in the longitudinal direction of the arm portion 51 in the resonator element 2. Therefore, the resonator element 2 can exhibit the above-described effects more prominently. Specifically, it is preferable that the region be present in a one-third portion of the total length (length in the Y-axis direction) of the vibrating arm 5 including the base end portion. In this manner, it is possible to reliably and effectively obtain the resonator element 2 that exhibits more excellent vibration characteristics than that of the related art.

Hereinafter, this will be proved based on results of simulation performed by the inventors. Meanwhile, hereinafter, a Z-cut quartz crystal plate is formed by patterning, and simulation using a resonator element having a bending vibration frequency (mechanical bending vibration frequency) of f=32.768 kHz is used as representative simulation. However, the inventors have confirmed that the following simulation results are rarely different from the above-described results in a range of 32.768 kHz±1 kHz of the bending vibration frequency f.

This simulation uses a resonator element in which the quartz crystal substrate 3 is patterned by wet etching. Therefore, as shown in FIG. 9, the grooves 52 and 53 have a shape in which a crystal plane of quartz crystal appears. Specifically, since an etching rate in the −X-axis direction is lower than an etching rate in the +X-axis direction, a side surface in the −X-axis direction is smoothly inclined, and a side surface in the +X-axis direction is inclined to be close to a vertical plane. Meanwhile, FIG. 9 shows the cross-section that is the same as FIG. 3.

In addition, the size of the vibrating arm 5 used in this simulation is 1000 μm in length, 120 μm in thickness, and 80 μm in width. Meanwhile, the inventors have confirmed that similar results to the following simulation results are obtained in spite of changes in the length, thickness, and width. In addition, this simulation uses the vibrating arm 5 in which the first and second driving electrodes 84 and 85 are not formed.

FIG. 10 is a graph showing a relationship between the widths W and the Q values of the bank portions 511a, 511b, 512a, and 512b when t/T is set to 0.208, 0.292, 0.375, 0.458, and 0.483. Meanwhile, the Q value is frequency-dependent. Accordingly, in this simulation, the Q value obtained under each condition of t/T is converted into the Q value (Q value after F conversion) at the time of 32.768 kHz and the reciprocal thereof is taken as a “high performance index 2”. The high performance index 2 is an index when a reciprocal, which is the greatest in all simulations, is set to 1 under each condition of t/T. Therefore, this means that the Q value increases as the high performance index 2 becomes close to 1.

Meanwhile, a method of converting the Q value to the Q value after F conversion is as follows.

The following calculation is performed using the following Expressions (8) and (9). In Expressions (8) and (9), π denotes a circular constant, k denotes the thermal conductivity of the vibrating arm 5 in the width direction, ρ denotes mass density, Cp denotes heat capacity, C denotes an elastic stiffness constant of expansion and contraction in the length direction of the vibrating arm 5, α denotes a thermal expansion coefficient of the vibrating arm 5 in the length direction, H denotes an absolute temperature, and f denotes a natural frequency. In addition, “a” denotes a width (effective width) when the vibrating arm 5 is regarded as a flat plate shape shown in FIG. 11. Although the grooves 52 and 53 are not formed in the vibrating arm 5 in FIG. 11, it is possible to perform conversion into the Q value after F conversion even if the value of “a” at this time is used.

$$\begin{matrix}{f}_{0} = \frac{π k}{2 ρ {Cpa}^{2}} & ( 8 ) \\ Q = \frac{ρ Cp}{C {α}^{2} H} \times \frac{1 + {( \frac{f}{{f}_{0}} )}^{2}}{\frac{f}{{f}_{0}}} & ( 9 )\end{matrix}$$

First, the natural frequency of the vibrating arm 5 used in the simulation is set to F1 and the obtained Q value is set to Q1, and thus the value of “a” satisfying the relations of f=F1 and Q=Q1 is obtained using Expressions (8) and (9). Then, the value of Q is calculated from Expression (9) by using the obtained “a” and setting the relation of f=32.768 kHz. The Q value obtained in this manner is the Q value after F conversion.

Here, if the high performance index 2 is equal to or greater than 0.8, the resonator element 2 having a sufficiently high Q value (having excellent vibration characteristics) is obtained, and if the high performance index 2 is equal to or greater than 0.9, the resonator element 2 having a higher Q value is obtained. Consequently, FIG. 12 shows a graph in which points A1 and A2 where the high performance index=0.8 when t/T=0.375, points B1 and B2 where the high performance index=0.8 when t/T=0.458, and points C1 and C2 where the high performance index=0.8 when t/T=0.48 are plotted. A quadratic equation (approximate equation) connecting the points A1, B1, and C1 having a smaller width W of each condition is expressed as the following Expression (10), and a quadratic equation (approximate equation) connecting the points A2, B2, and C2 having a larger width W of each condition is expressed as the following Expression (11), where a unit is [μm].

$$\begin{matrix}- 8.835 \times {10}^{1} \times {( \frac{t}{T} )}^{2} + 8.737 \times {10}^{1} \times ( \frac{t}{T} ) - 1.872 \times {10}^{1} & ( 10 ) \\ 1.136 \times {10}^{2} \times {( \frac{t}{T} )}^{2} - 1.385 \times {10}^{2} \times ( \frac{t}{T} ) + 5.205 \times {10}^{1} & ( 11 )\end{matrix}$$

Therefore, it is possible to obtain the resonator element 2 having excellent vibration characteristics by having a width W3 using Expression (10) as a lower limit and using Expression (11) as an upper limit, that is, by satisfying Expressions (6) and (7) mentioned above.

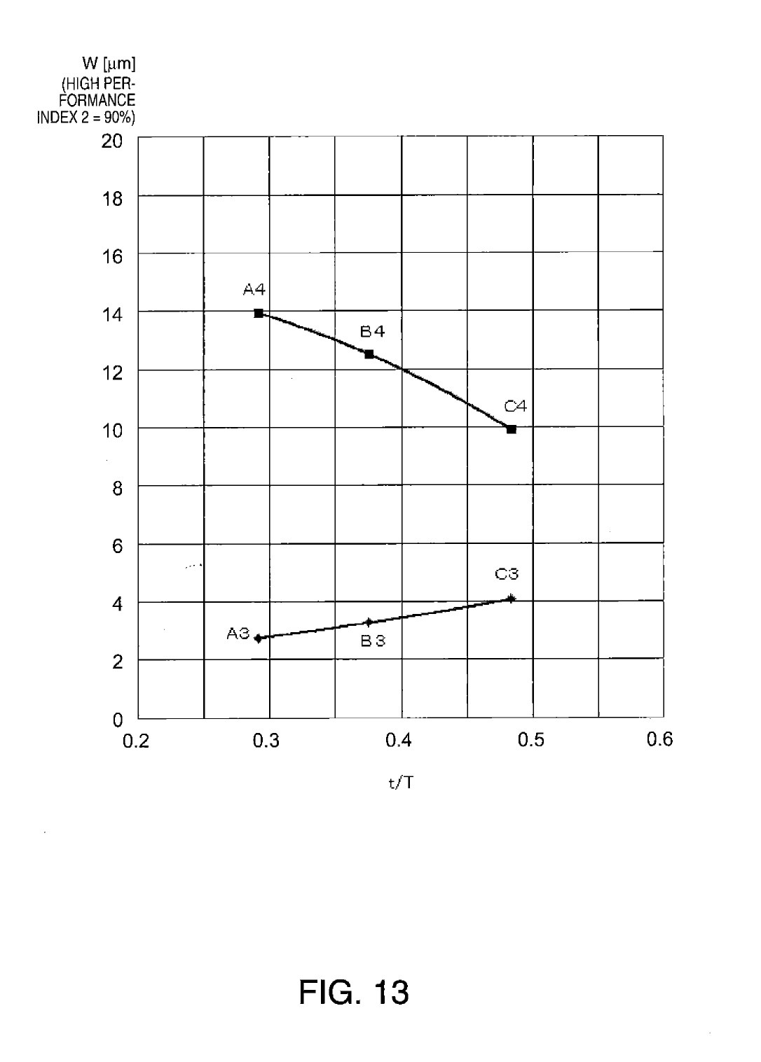

In addition, FIG. 13 shows a graph in which points A3 and A4 where the high performance index=0.9 when t/T=0.292, points B3 and B4 where the high performance index=0.9 when t/T=0.375, and points C3 and C4 where the high performance index=0.9 when t/T=0.48 are plotted. A quadratic equation (approximate equation) connecting the points A3, B3, and C3 having a smaller width W of each condition is expressed as the following Expression (12), and a quadratic equation (approximate equation) connecting the points A4, B4, and C4 having a larger width W of each condition is expressed as the following Expression (13), where a unit is [μm].

$$\begin{matrix}6.155 \times {( \frac{t}{T} )}^{2} + 2.099 \times ( \frac{t}{T} ) + 1.617 & ( 12 ) \\ - 3.773 \times {10}^{1} \times {( \frac{t}{T} )}^{2} + 8.272 \times ( \frac{t}{T} ) + 1.474 \times {10}^{1} & ( 13 )\end{matrix}$$

Therefore, it is possible to obtain the resonator element 2 having more excellent vibration characteristics by satisfying both the following Expressions (14) and (15), where a unit is [μm].

$$\begin{matrix} 0.292 ≦ \frac{t}{T} ≦ 0.483 & ( 14 ) \\ 6.155 \times {( \frac{t}{T} )}^{2} + 2.099 \times ( \frac{t}{T} ) + 1.617 ≦ W ≦ - 3.773 \times {10}^{1} \times {( \frac{t}{T} )}^{2} + 8.272 \times ( \frac{t}{T} ) + 1.474 \times {10}^{1} & ( 15 )\end{matrix}$$

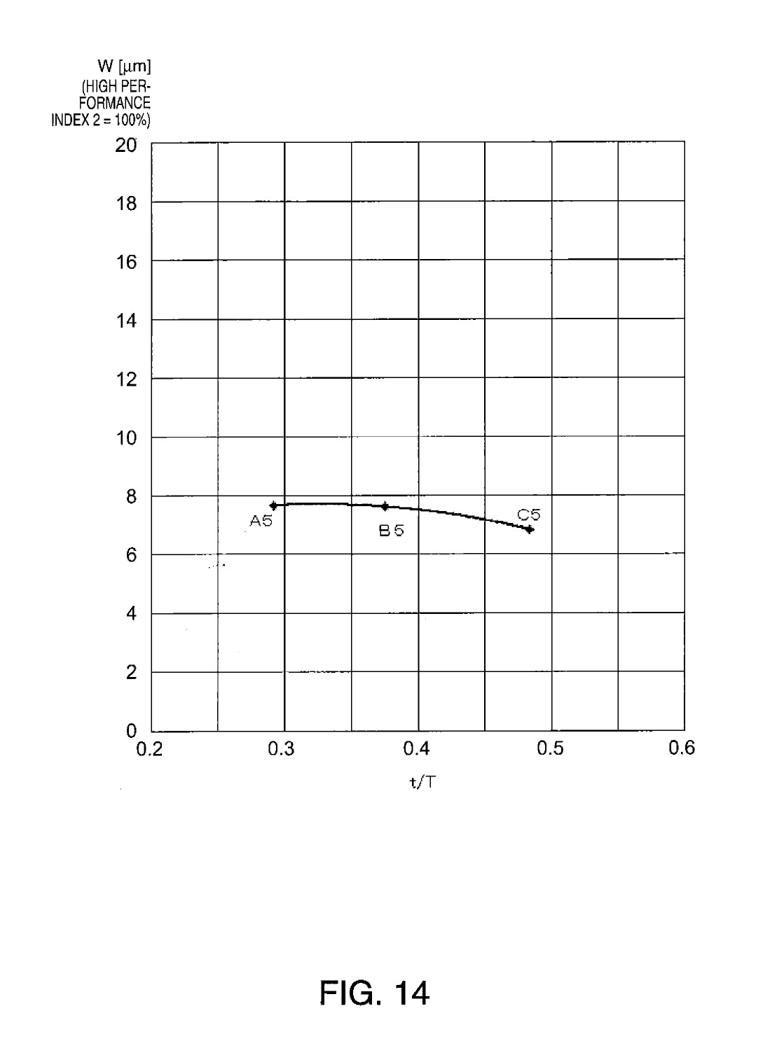

In addition, FIG. 14 shows a graph in which a point A5 where the high performance index=1 when t/T=0.292, a point B5 where the high performance index=1 when t/T=0.375, and a point C5 where the high performance index=1 when t/T=0.48 are plotted. A quadratic equation (approximate equation) connecting the points A5, B5, and C5 is expressed as the following Expression (16), where a unit is [μm].

$$- 3.448 \times {10}^{1} \times {( \frac{t}{T} )}^{2} + 2.237 \times {10}^{1} \times ( \frac{t}{T} ) + 4.079 \qquad ( 16 )$$

Therefore, it is possible to obtain the resonator element 2 having more excellent vibration characteristics by satisfying both the following Expressions (17) and (18).

$$\begin{matrix}0.292 ≦ \frac{t}{T} ≦ 0.483 & ( 17 ) \\ W = - 3.448 \times {10}^{1} \times {( \frac{t}{T} )}^{2} + 2.237 \times {10}^{1} \times ( \frac{t}{T} ) + 4.079 & ( 18 )\end{matrix}$$

The depths t of the grooves 52, 53, 62, and 63 and the widths W of the bank portions 511a, 511b, 512a, and 512b have been described so far.

Further, when a resonance frequency of a basic vibration mode (X reverse phase mode) is set to ω0 and a resonance frequency of a vibration mode (spurious vibration mode), which is different from the basic vibration mode (X reverse phase mode), is set to ω1, the resonator element 2 satisfies the relation of the following Expression (19). Thus, the coupling of the spurious vibration mode to the basic vibration mode is reduced, and thus the resonator element 2 having excellent vibration characteristics (characteristics of excellent vibration balancing and little vibration leakage) is obtained.

$$\frac{\vert ω 0 - ω 1 \vert}{ω 0} ≧ 0.124 \qquad ( 19 )$$

Hereinafter, this will be proved based on results of an experiment performed by the inventors. Meanwhile, the experiment was performed by forming a Z-cut quartz crystal plate by patterning and using the resonator element having the size shown in FIG. 15. In addition, in this experiment, an “X in-phase mode” in which the vibrating arms 5 and 6 bend and vibrate to the same side in the X-axis direction is adopted as a spurious vibration mode, but the spurious vibration mode includes a “Z in-phase mode” in which the vibrating arms 5 and 6 bend and vibrate to the same side of the Z-axis, a “Z reverse phase mode” in which the vibrating arms 5 and 6 bend and vibrate to opposite sides of the Z-axis, a “torsional in-phase mode” in which the vibrating arms 5 and 6 are twisted in the same direction about the Y-axis, a “torsional reverse phase mode” in which the vibrating arms 5 and 6 are twisted in opposite directions about the Y-axis, and the like, in addition to the X in-phase mode. Resonance frequencies of the spurious vibration modes other than the X in-phase mode can be regarded as being equal to the resonance frequency of the X in-phase mode.

The following Table 1 shows a resonance frequency ω0 of a basic vibration mode (X reverse phase mode), a resonance frequency ω1 of an X in-phase mode, a frequency difference Δf, and a high performance index 3 of each of four samples SAM1 to SAM4. Here, Δf is expressed as the following Expression (20), and the high performance index 3 is an index when the highest Q value in all the samples is set to 1. Therefore, this means that the Q value increases as the high performance index 3 becomes close to 1. In addition, FIG. 16 shows a graph in which the high performance indexes 3 of the samples SAM1 to SAM4 are plotted.

$$Δ f = \frac{\vert ω 0 - ω 1 \vert}{ω 0} \qquad ( 20 )$$

TABLE 1

| | X | X | | | |
|---|---|---|---|---|---|
| | in-phase | reverse phase | | | High |
| | mode | mode | | | performance |
| | [kHz] | [kHz] | \|Δf\| | Q | index 3 |
| SAM1 | 29.797 | 32.720 | 8.9% | 7.309 | 0.54 |
| SAM2 | 29.498 | 32.724 | 9.9% | 8.709 | 0.65 |
| SAM3 | 28.444 | 32.713 | 13.0% | 11.183 | 0.83 |
| SAM4 | 26.419 | 32.972 | 19.9% | 13.500 | 1.00 |

Here, if the high performance index 3 is equal to or greater than 0.8, the resonator element 2 having a sufficiently high Q value (having excellent vibration characteristics) is obtained, if the high performance index 3 is equal to or greater than 0.9, the resonator element 2 having a higher Q value is obtained, and if the high performance index 3=1, the resonator element 2 having a much higher Q value is obtained. A quadratic equation (approximate equation) connecting the high performance indexes 3 of the samples is expressed as the following Expression (21). For this reason, it can be seen from Expression (21) that the relation of Δf=0.124 is satisfied when the high performance index 3=0.8, the relation of Δf=0.15 is satisfied when the high performance index 3=0.9, and the relation of Δf=0.2 is satisfied when the high performance index=1.

−4.016×10¹×Δf²+1.564×10¹×Δf−5.238×10⁻¹ (21)

Therefore, it is proved that the resonator element 2 having excellent vibration characteristics is obtained by satisfying Expression (19) mentioned above, that the resonator element 2 having more excellent vibration characteristics is obtained by satisfying Expression (22) mentioned below, and that the resonator element 2 having much more excellent vibration characteristics is obtained by satisfying Expression (23) mentioned below.

$$\begin{matrix}\frac{ω 0 - ω 1 \vert}{ω 0} ≧ 0.145 & ( 22 ) \\ \frac{\vert ω 0 - ω 1 \vert}{ω 0} ≧ 0.2 & ( 23 )\end{matrix}$$

### Second Embodiment

Hereinafter, a resonator according to a second embodiment of the invention will be described.

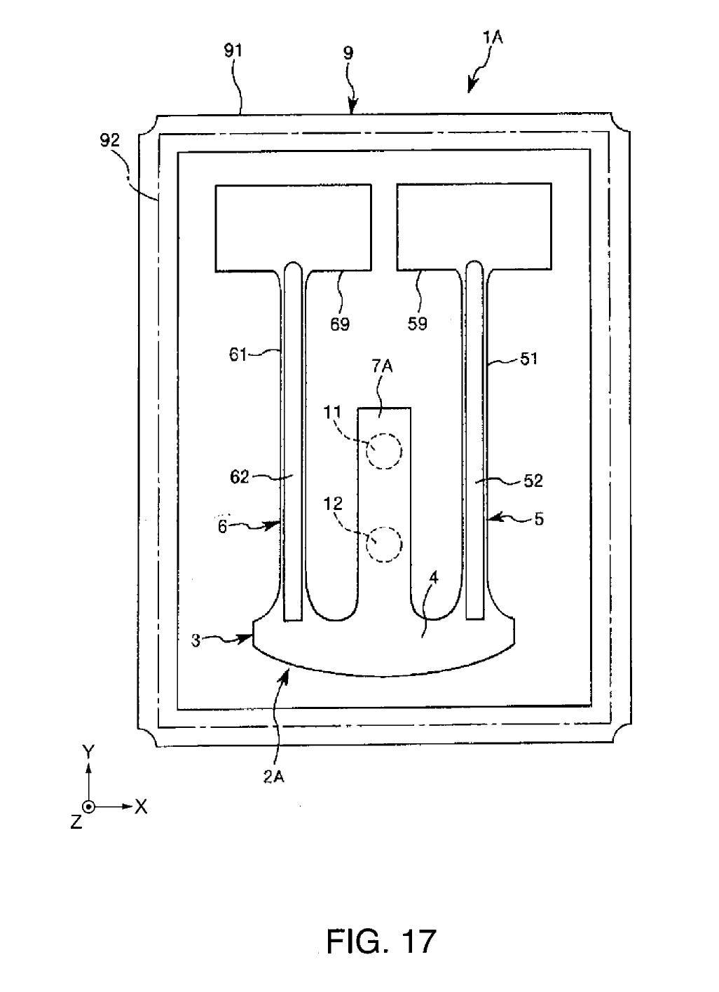

FIG. 17 is a top view of the resonator according to the second embodiment of the invention.

Hereinafter, the resonator according to the second embodiment will be described focusing on the differences from the first embodiment described above, and a description of similar matters will be omitted.

The resonator according to the second embodiment of the invention is similar to that of the first embodiment described above except that the configuration of a resonator element is different. Meanwhile, the same components as in the first embodiment described above are denoted by the same reference numerals.

As shown in FIG. 17, in a resonator 1A, a support portion 7A of a resonator element 2A extends in a +Y-axis direction from a distal end of the base portion 4 and is located between the vibrating arms 5 and 6. The resonator element 2A is fixed to the base 91 by the support portion 7A through the conductive adhesive members 11 and 12. Based on such a configuration, it is possible to reduce the size of the resonator element 2A as compared with the resonator element 2 of the first embodiment described above.

Also in the second embodiment, the same effects as in the first embodiment described above can be exhibited.

### Third Embodiment

Next, a resonator according to a third embodiment of the invention will be described.

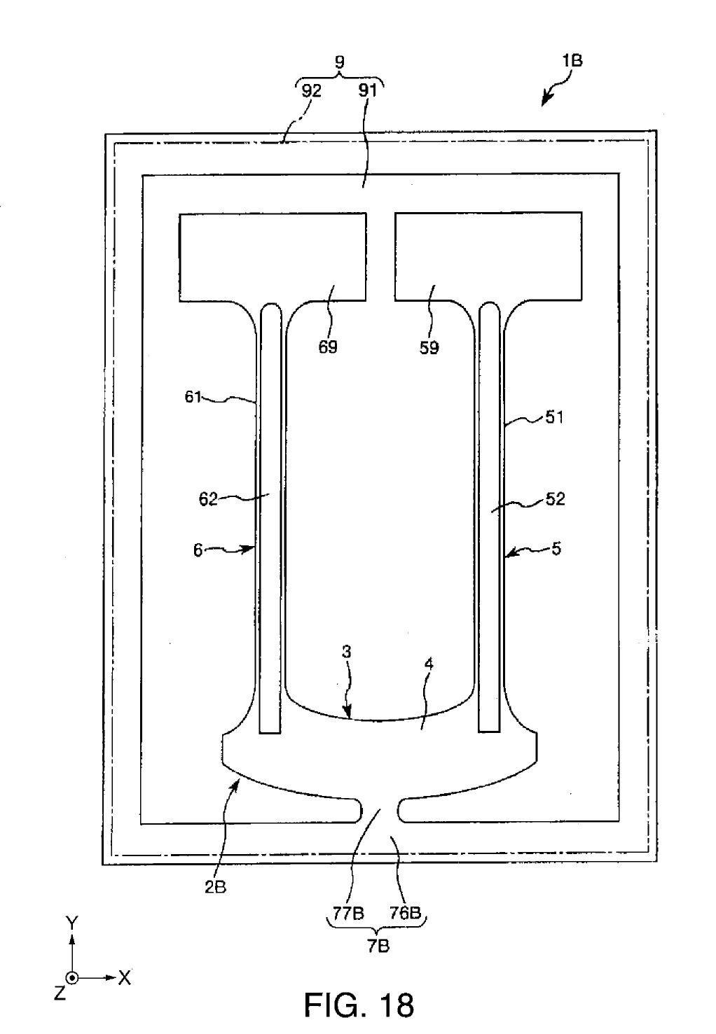

FIG. 18 is a top view of the resonator according to the third embodiment of the invention.

Hereinafter, the resonator according to the third embodiment will be described focusing on the differences from the first embodiment described above, and a description of similar matters will be omitted.

The resonator according to the third embodiment of the invention is similar to that of the first embodiment described above except that the configuration of a resonator element is different. Meanwhile, the same components as in the first embodiment described above are denoted by the same reference numerals.

As shown in FIG. 18, a support portion 7B of a resonator element 2B has a frame-shaped frame portion 76B that surrounds the base portion 4 and the vibrating arms 5 and 6, and a connecting portion 77B that connects the frame portion 76B and a base end portion of the base portion 4 to each other. The resonator element 2B is fixed to the package 9 by sandwiching the frame portion 76B between the base 91 and the lid 92 which have a cavity shape. According to such a configuration, since fixing using the conductive adhesive members 11 and 12 is not necessary, it is possible to reduce, for example, the occurrence of outgassing. Meanwhile, it is possible to connect the first and second driving electrodes 84 and 85 and the external terminals 953 and 963 to each other through the frame portion 76B.

Also in the third embodiment, the same effects as in the first embodiment described above can be exhibited.

### Modification Example of Resonator Element

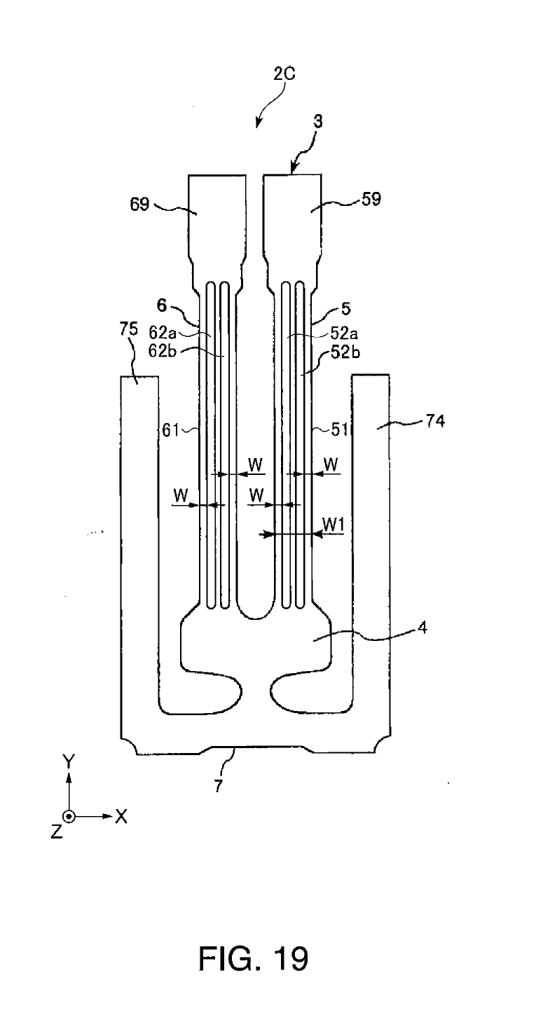

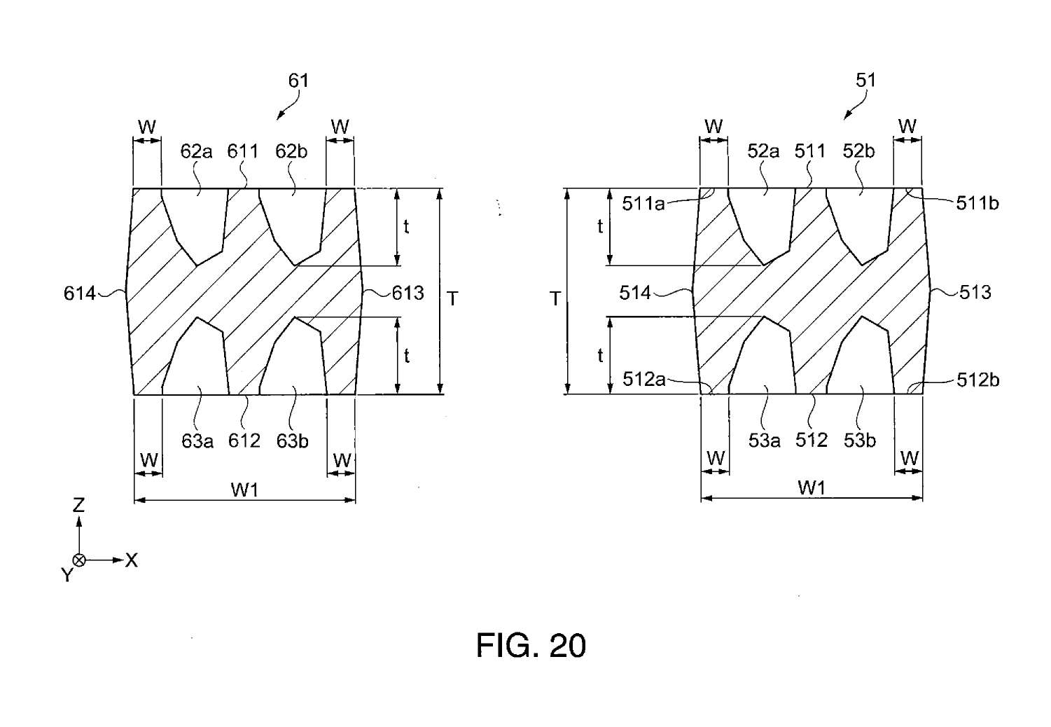

Next, a resonator element according to a modification example of the invention will be described with reference to FIG. 19 and FIG. 20. FIG. 19 is a plan view showing a modification example of a resonator element included in the resonator according to the invention. FIG. 20 is a cross-sectional view showing a cross-section of an arm portion of the resonator element.

Hereinafter, a resonator element according to a modification example will be described focusing on the differences from the first to third embodiments described above, and a description of similar matters will be omitted. Although the above-described embodiments have a configuration in which one groove is provided in each principal surface of each vibrating arm, the number of grooves is not particularly limited and may be two or more. For example, two grooves that are lined up along the X-axis direction may be provided in each principal surface.

The resonator element according to this modification example is similar to that of the first embodiment described above except that the number of grooves provided in each principal surface of each vibrating arm is different. Meanwhile, the same components as the resonator element of the first embodiment described above are denoted by the same reference numerals.

A resonator element 2C according to a modification example is provided with two bottomed grooves 52a and 52b opened to the principal surface 511 of the vibrating arm 5, two bottomed grooves 53a and 53b opened to the principal surface 512, two bottomed grooves 62a and 62b opened to a principal surface 611 of the vibrating arm 6, and two bottomed grooves 63a and 63b opened to a principal surface 612.

The grooves 52a, 52b, 53a, and 53b and the grooves 62a, 62b, 63a, and 63b extend in the Y-axis direction, the distal ends thereof are located at a boundary between the arm portion 51 and the hammerhead 59 and at a boundary between the arm portion 61 and the hammerhead 69, respectively, and the base ends thereof are located at the base portion 4. The two grooves 52a and 52b are provided to be lined up along the X-axis direction, and similarly, the respective pairs of grooves 53a and 53b, grooves 62a and 62b, and grooves 63a and 63b are provided to be lined up.

At this time, in the grooves 52b, 53b, 52a, and 53a, a width W along the X-axis direction between the side surface 513, which is one outer edge of the vibrating arm 5, and edge portions of the grooves 52b and 53b on the side surface 513 side and a width W along the X-axis direction between the side surface 514, which is the other outer edge of the vibrating arm 5, and edge portions of the grooves 52a and 53a on the side surface 514 side are disposed in a similar manner to those in the first embodiment described above. Similarly, the grooves 62b, 63b, 62a, and 63a are disposed in the vibrating arm 6.

In addition, the grooves 52a, 52b, 53a, 53b, 62a, 62b, 63a, and 63b are configured in a similar manner to those in the first embodiment described above when the maximum depth thereof is set to t and the thicknesses of the vibrating arms 5 and 6 are set to T.

Also in such configurations of the grooves 52a, 52b, 53a, 53b, 62a, 62b, 63a, and 63b, it is possible to reduce thermoelastic loss and to exhibit excellent vibration characteristics. Meanwhile, the lengths of the grooves 52a, 52b, 53a, 53b, 62a, 62b, 63a, and 63b are not limited, and may be configured such that the distal ends of the grooves 52a, 52b, 53a, 53b, 62a, 62b, 63a, and 63b extend up to the regions of the hammerheads 59 and 69.

### 2. Oscillator

Next, an oscillator to which the resonator element according to the invention is applied (oscillator according to the invention) will be described.

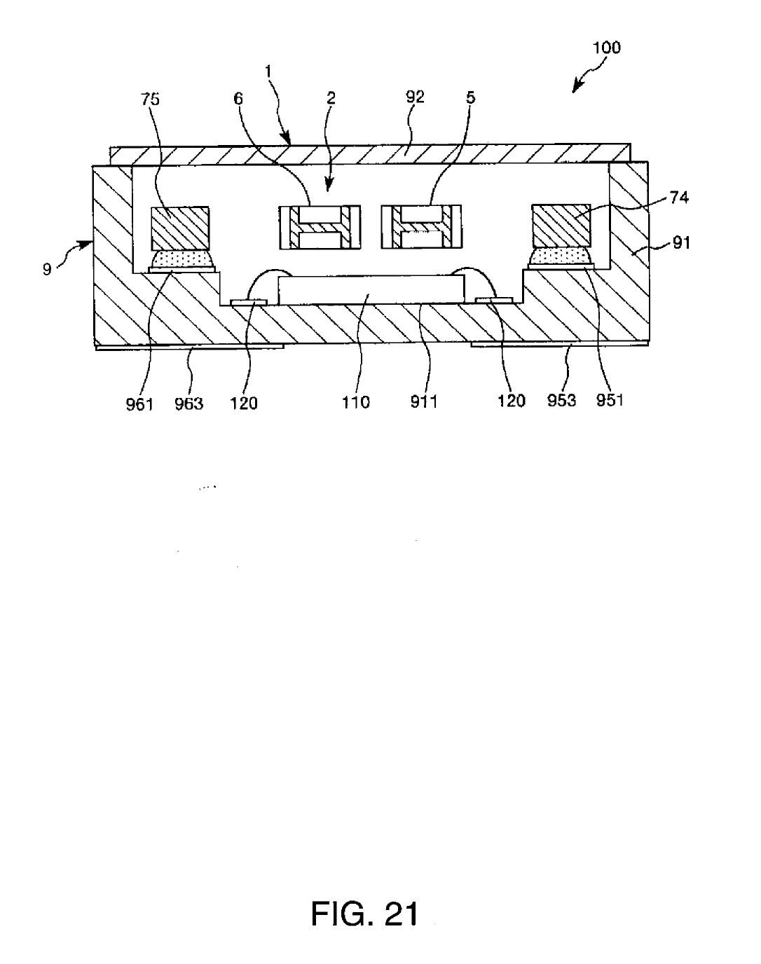

FIG. 21 is a cross-sectional view showing an oscillator according to a preferred embodiment of the invention.

An oscillator 100 shown in FIG. 21 includes the resonator 1 and an IC chip 110 for driving the resonator element 2. Hereinafter, the oscillator 100 will be described focusing on the differences from the above-described resonator, and a description of similar matters will be omitted.

As shown in FIG. 21, in the oscillator 100, the IC chip 110 is fixed to the concave portion 911 of the base 91. The IC chip 110 is electrically connected to a plurality of internal terminals 120 formed on the bottom surface of the concave portion 911. The plurality of internal terminals 120 include internal terminals connected to the connecting terminals 951 and 961 and internal terminals connected to the external terminals 953 and 963. The IC chip 110 includes an oscillation circuit for controlling the driving of the resonator element 2. When the resonator element 2 is driven by the IC chip 110, it is possible to extract a signal having a predetermined frequency.

### 3. Electronic Apparatus

Next, an electronic apparatus to which the resonator element according to the invention is applied (electronic apparatus according to the invention) will be described.

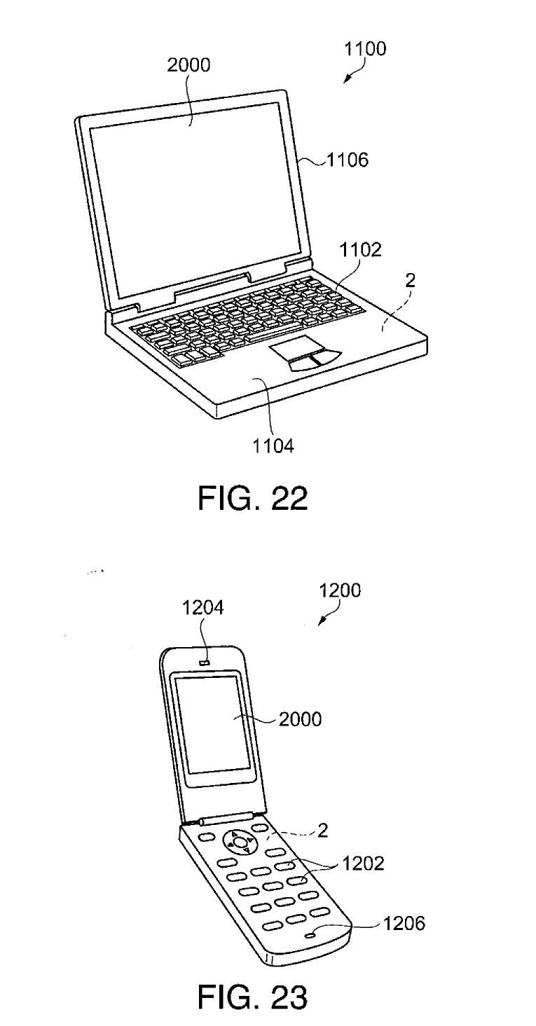

FIG. 22 is a perspective view showing a configuration of a mobile (or notebook) personal computer to which the electronic apparatus according to the invention is applied. In FIG. 22, a personal computer 1100 is constituted by a main body 1104 including a keyboard 1102 and a display unit 1106 including a display unit 2000, and the display unit 1106 is supported so as to be rotatable with respect to the main body 1104 through a hinge structure. The resonator element 2 that functions as a filter, a resonator, a reference block, and the like is built into the personal computer 1100.

FIG. 23 is a perspective view showing a configuration of a mobile phone (PHS is also included) to which the electronic apparatus according to the invention is applied. In FIG. 23, a mobile phone 1200 includes a plurality of operation buttons 1202, an earpiece 1204, and a mouthpiece 1206, and a display unit 2000 is disposed between the operation buttons 1202 and the earpiece 1204. The resonator element 2 that functions as a filter, a resonator, and the like is built into the mobile phone 1200.

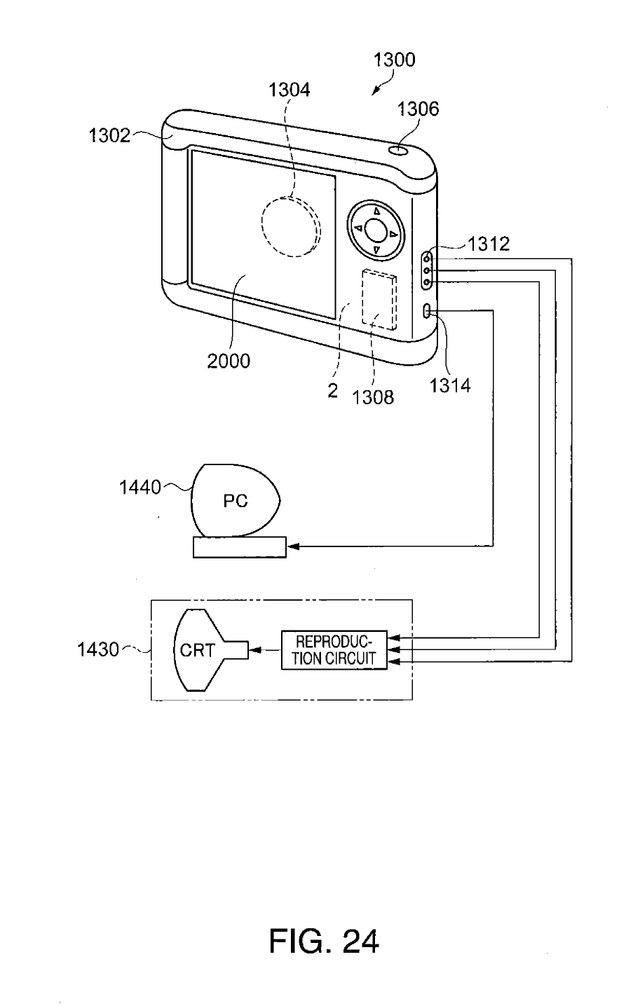

FIG. 24 is a perspective view showing a configuration of a digital still camera to which the electronic apparatus according to the invention is applied. Meanwhile, connection with an external device is simply shown in FIG. 24. Here, a silver halide photograph film is exposed to light according to an optical image of a subject in a typical camera, while a digital still camera 1300 generates an imaging signal (image signal) by performing photoelectric conversion of an optical image of a subject using an imaging element, such as a charge coupled device (CCD).

A display unit is provided on the back of a case (body) 1302 in the digital still camera 1300, so that display based on the imaging signal of the CCD is performed. The display unit functions as a viewfinder that displays a subject as an electronic image. In addition, a light receiving unit 1304 including an optical lens (imaging optical system), a CCD, and the like is provided on the front side (back side in FIG. 24) of the case 1302.

When a photographer checks a subject image displayed on the display unit and presses a shutter button 1306, an imaging signal of the CCD at that point in time is transferred and stored in a memory 1308. In addition, in the digital still camera 1300, a video signal output terminal 1312 and an input/output terminal for data communication 1314 are provided on the side surface of the case 1302. In addition, as shown in the drawing, a television monitor 1430 is connected to the video signal output terminal 1312 and a personal computer 1440 is connected to the input/output terminal for data communication 1314 when necessary. Further, an imaging signal stored in the memory 1308 is configured to be output to the television monitor 1430 or the personal computer 1440 by a predetermined operation. The resonator element 2 that functions as a filter, a resonator, and the like is built into the digital still camera 1300.

Meanwhile, the electronic apparatus including the resonator element according to the invention can be applied not only to the personal computer (mobile personal computer) shown in FIG. 22, the mobile phone shown in FIG. 23, and the digital still camera shown in FIG. 24 but also to an ink jet type discharge apparatus (for example, an ink jet printer), a laptop type personal computer, a television, a video camera, a video tape recorder, a car navigation apparatus, a pager, an electronic organizer (an electronic organizer with a communication function is also included), an electronic dictionary, an electronic calculator, an electronic game machine, a word processor, a workstation, a video phone, a television monitor for security, electronic binoculars, a POS terminal, medical equipment (for example, an electronic thermometer, a sphygmomanometer, a blood sugar meter, an electrocardiographic measurement device, an ultrasonic diagnostic apparatus, and an electronic endoscope), a fish detector, various measurement apparatuses, instruments (for example, instruments for vehicles, aircraft, and ships), a flight simulator and the like.

### 4. Moving Object

Next, a moving object to which the resonator element according to the invention is applied (moving object according to the invention) will be described.

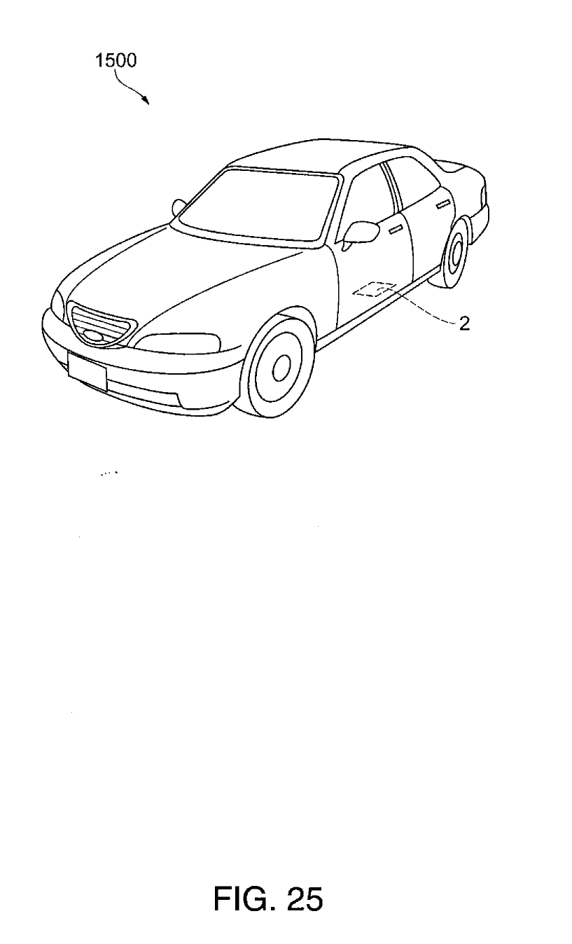

FIG. 25 is a perspective view showing a vehicle to which the moving object according to the invention is applied. The resonator element 2 is mounted in a vehicle 1500. The resonator element 2 can be widely applied to an electronic control unit (ECU), such as a keyless entry, an immobilizer, a car navigation system, a car air-conditioner, an anti-lock brake system (ABS), an airbag, a tire pressure monitoring system (TPMS), an engine control, a battery monitor of a hybrid vehicle or an electric vehicle, and a vehicle body position control system.

Although the resonator element, the resonator, the oscillator, the electronic apparatus, and the moving object according to the invention have been described so far with reference to the illustrated embodiments, the invention is not limited thereto, and the configuration of each portion may be replaced with any configuration having the same function. In addition, any other structures may be added to the invention. In addition, the embodiments described above may be appropriately combined.

In addition, in the above-described embodiments, a quartz crystal substrate is used as a piezoelectric substrate. However, various piezoelectric substrates formed of, for example, lithium niobate (LiNbO₃), lithium tantalate (LiTaO₃), lithium tetraborate (Li₂B₄O₇), potassium niobate (KNbO₃), gallium phosphate (GaPO₄), langasite (La₃Ga₅SiO₁₄), gallium arsenide (GaAs), aluminum nitride (AlN), zinc oxide (ZnO, Zn₂O₃), barium titanate (BaTiO₃), lead titanate (PbPO₃), lead zirconate titanate (PZT), sodium potassium niobate ((K,Na)NbO₃), bismuth ferrite (BiFeO₃), sodium niobate (NaNbO₃), bismuth titanate (Bi₄Ti₃O₁₂) or sodium bismuth titanate (Na_{0.5}Bi_{0.5}TiO₃) may be used instead of the quartz crystal substrate.

In addition, it is possible to form a resonator element using a material other than a piezoelectric material. For example, it is also possible to form a resonator element using a silicon semiconductor material. In addition, a vibration (driving) method of the resonator element is not limited to a piezoelectric driving method. It is also possible to exhibit the configuration of the invention and the effects thereof in resonator elements such as an electrostatic driving type using an electrostatic force and a Lorentz driving type using a magnetic force, in addition to a piezoelectric driving type using a piezoelectric substrate. In addition, the terms used in the specification or the drawings at least once together with a different term having a broader or similar meaning can be replaced with the different term in any portion of the specification or the drawings.

The entire disclosure of Japanese Patent Application No. 2013-075411, filed Mar. 29, 2013, and Japanese Patent Application No. 2014-021141, filed Feb. 6, 2014 is expressly incorporated by reference herein.

What is claimed is:

1. A resonator element comprising:
a base portion; and
a pair of vibrating arms that extend in a first direction from the base portion when seen in a plan view and are lined up along a second direction perpendicular to the first direction,
wherein the vibrating arm includes
a weight portion, and
an arm portion that is disposed between the weight portion and the base portion when seen in a plan view,
wherein the resonator element has a basic vibration mode in which the pair of vibrating arms bend and vibrate by alternately repeating mutual approach and separation along the second direction,
wherein when a length of the vibrating arm along the first direction is set to L and a length of the weight portion along the first direction is set to H, the following relation is satisfied, and
$$0.183 ≦ \frac{H}{L} ≦ 0.597$$
wherein when a resonance frequency of the basic vibration mode is set to ω0 and a resonance frequency of another vibration mode different from the basic vibration mode is set to ω1, the following relation is satisfied
$$\frac{\vert ω 0 - ω 1 \vert}{ω 0} ≧ 0.124 .$$

2. The resonator element according to claim 1,
wherein a groove is provided in at least one of a pair of principal surfaces of the vibrating arm which have a front-back relationship,
wherein when a thickness of the vibrating arm is set to T and a depth of the groove is set to t, the following relation is satisfied, and
$$0.375 ≦ \frac{t}{T} ≦ 0.483$$
wherein in the one principal surface of the vibrating arm, when a width along the second direction between one outer edge of the vibrating arm and an edge portion of the groove on the one outer edge side and a width along the second direction between the other outer edge of the vibrating arm and an edge portion of the groove on the other outer edge side, when seen in a plan view, are set to W[μm], the following relation is satisfied
$$- 8.835 \times {10}^{1} \times {( \frac{t}{T} )}^{2} + 8.737 \times {10}^{1} \times ( \frac{t}{T} ) - 1.872 \times {10}^{1} ≦ W ≦ 1.136 \times {10}^{2} \times {( \frac{t}{T} )}^{2} - 1.385 \times {10}^{2} \times ( \frac{t}{T} ) + 5.205 \times {10}^{1} .$$

3. The resonator element according to claim 2, wherein the following relation is satisfied
$$0.455 ≦ \frac{t}{T} ≦ 0.483 .$$

4. The resonator element according to claim 2, wherein a relation of 100 μm≦T≦300 μm is satisfied.

5. The resonator element according to claim 1, wherein when a resonance frequency of the basic vibration mode is set to f and a relaxation vibration frequency is set to fm, the following relation is satisfied
$$\frac{f}{fm} > 1.$$

6. The resonator element according to claim 1, wherein the another vibration mode is an in-phase mode in which the pair of vibrating arms are displaced in the same direction.

7. The resonator element according to claim 1, wherein the weight portion has a width that is wider than a width of the arm portion along the second direction.

8. A resonator comprising:
the resonator element according to claim 1; and
a package in which the resonator element is mounted.

9. An oscillator comprising:
the resonator element according to claim 1; and
a circuit.

10. An electronic apparatus comprising the resonator element according to claim 1.

11. A moving object comprising the resonator element according to claim 1.
